(19) United States
(12) Patent Application Publication
(10) Pub. No.: US 2026/0308802 A1
(43) Pub. Date: Oct. 8, 2026

(54) METAL-ORGANIC FRAMEWORKS/TRANSITION METAL DICHALCOGENIDES VAN DER WAALS HETEROSTRUCTURES FOR ULTRA STRONG MICROWAVE ABSORPTION

(71) Applicant: City University of Hong Kong, Hong Kong (HK)

(72) Inventors: Hua ZHANG, Hong Kong (HK); Zhenyu SHI, Hong Kong (HK); Yuxuan WU, Hong Kong (HK); Xinyang RUAN, Hong Kong (HK)

(21) Appl. No.: 19/438,702

(22) Filed: Jan. 2, 2026

Related U.S. Application Data
(60) Provisional application No. 63/741,459, filed on Jan. 3, 2025.

(51) Int. Cl. C30B 19/12; C01G 41/00; C30B 29/54

(52) U.S. Cl. CPC C30B 19/12; C01G 41/006; C30B 29/54; C01P 2002/82; C01P 2002/85; C01P 2004/03; C01P 2004/04; C01P 2004/24; C01P 2006/40

(57) ABSTRACT

The present invention provides a general and scalable method for constructing metal-organic framework (MOF) and unconventional-phase transition-metal dichalcogenide (TMD) van der Waals epitaxial heterostructures. The method enables the oriented growth of diverse MOFs, including 1D, 2D, and porphyrinic frameworks with single- or mixed-metal centers, on metastable 1T′-TMD nanosheets such as 1T′-WS₂ and 1T′-MoS₂. The epitaxial interface formed between the MOF and TMD produces a well-defined crystallographic alignment and induces strong interfacial polarization and optimized dielectric behavior. As a representative embodiment, Cu-M/1T′-WS₂ exhibits an ultralow reflection loss of −89.8 dB and a broad effective absorption bandwidth. The disclosed strategy establishes a versatile platform for designing high-performance electromagnetic-wave absorbing materials and other advanced organic-inorganic heterostructures.

### CROSS-REFENCE TO RELATED APPLICATIONS

The present application claims the priority from the U.S. provisional patent application Ser. No. 63/741,459 filed Jan. 3, 2025, and the disclosure of which is incorporated herein by reference in its entirety.

### FIELD OF THE INVENTION

The present invention generally relates to at least the fields of material science and nanotechnology, specifically to the synthesis of van der Waals epitaxial heterostructures.

### BACKGROUND OF THE INVENTION

With the growth of fifth-generation (5G) and emerging sixth-generation (6G) communication technologies, the widespread use of mobile electronic devices has intensified electromagnetic pollution. Such interference can impair electronic performance and may pose risks to human health. Accordingly, there is a strong demand for high-performance electromagnetic-wave (EMW) absorption materials.

Heterostructures formed by combining materials with distinct chemical compositions, lattice structures, or electronic properties often exhibit synergistically enhanced functionalities. Two-dimensional (2D) nanomaterial-based heterostructures have been widely explored in electronics, optoelectronics, and electrocatalysis due to their tunable physicochemical characteristics. In particular, 2D transition-metal dichalcogenides (TMDs) are promising EMW absorbers because of their ultrathin morphology, large surface area, diverse compositions, and adjustable electrical properties. Integrating TMD nanosheets with dielectric materials such as metal-organic frameworks (MOFs), polymers, or metal oxides can further improve dielectric behavior and provide additional EMW scattering and reflection interfaces.

However, conventional epitaxial heterostructures are generally limited by lattice-matching requirements and the covalent-bonded nature of the interface. Materials with substantial lattice mismatch, typically exceeding five percent, cannot be epitaxially integrated without generating considerable interfacial disorder, which may degrade intrinsic properties. As a result, organic/inorganic heterostructures with clean and well-defined interfaces are difficult to achieve. Furthermore, most reported TMD-based composites rely on thermodynamically stable 2H phases or mixed 2H/1T/1T′ structures, which limit electrical conductivity and thus restrict EMW attenuation performance. The large structural mismatch between TMDs and secondary dielectric materials, such as MOFs, also makes it challenging to achieve controlled, reproducible interfacial growth, leading to batch-to-batch variability and difficulty in studying interfacial polarization mechanisms.

Van der Waals (vdW) integration offers an alternative pathway for constructing heterostructures without covalent bonds or lattice-matching constraints. By assembling prefabricated building blocks through vdW forces, artificial heterostructures and superlattices with atomically clean interfaces can be created, enabling unprecedented combinations of materials and structures.

Various techniques have been proposed for preparing vdW heterostructures, typically involving the fabrication of 2D nanosheets, their isolation through wet or dry transfer, and subsequent physical assembly. However, these assembly-based approaches do not enable epitaxial control of the interface, nor do they permit growth of crystalline MOFs on metastable TMD templates. Although these strategies allow construction of 0D, 1D, 2D, and 3D vdW heterostructures, they often suffer from low yield, complex processing steps, and limited scalability, making them unsuitable for large-scale applications requiring precise control of chemical composition, electronic properties, and spatial configuration.

In addition to process-related limitations, material-related constraints further restrict the development of high-quality vdW heterostructures. Several prior works have explored unconventional-phase TMDs. For instance, U.S. Application Publication No. 20230416935A1¹ discloses hybrids of single-atomically dispersed metals on unconventional-phase TMD nanosheets. Zeng et al.² reported electrochemical lithiation for preparing single-layer TMDs, although the method requires hazardous lithium metal and is incompatible with metastable phases. Lin et al.³ used quaternary ammonium-assisted intercalation but required large, intact TMD crystals that limit generality. Huang et al.⁴ described solution-phase epitaxial growth of noble metals on MoS₂, but the templates were mixed-phase rather than pure 1T′. More recently, Shi et al.⁵ demonstrated phase-dependent metal growth on TMDs, showing that 1T′ phases can stabilize single-atom species.

Despite these developments, no existing technique provides a general, scalable, and controllable solution-phase method for growing crystalline MOFs epitaxially on metastable 1T′-TMD nanosheets with defined orientation and atomically clean vdW interfaces. Accordingly, there remains a need in the art for methods capable of constructing organic/inorganic vdW epitaxial heterostructures with controlled interface structure, high reproducibility, and functional properties suitable for EMW absorption and other advanced applications.

### SUMMARY OF THE INVENTION

In view of the limitations of existing techniques for constructing organic/inorganic heterostructures, particularly the inability to achieve epitaxial control, the lack of scalability, and the difficulty in forming well-defined interfaces on metastable transition-metal dichalcogenides (TMDs), the present invention aims to provide improved methods and materials that overcome these deficiencies.

The present invention provides a general, scalable, and solution-processable strategy for preparing vdW organic/inorganic epitaxial heterostructures comprising a metal-organic framework (MOF) epitaxially grown on a metastable 1T′-phase TMD nanosheet. In certain embodiments, the invention utilizes atomically thin 1T′-WS₂ nanosheets as crystalline templates and enables the epitaxial growth of a MOF, such as a Cu-HHTP framework, to form well-oriented MOF/TMD vdW heterostructures. The wet-chemical growth process affords precise control over crystallographic orientation, interface quality, and heterostructure morphology, thereby enabling reproducible and large-area fabrication.

In a first aspect, the present invention provides a van der Waals epitaxial heterostructure, which includes a transition-metal dichalcogenide nanosheet in a metastable 1T′ phase, and a metal-organic framework disposed on a basal surface of the transition-metal dichalcogenide nanosheet. The metal-organic framework exhibits an epitaxial crystallographic orientation aligned with a lattice plane of the transition-metal dichalcogenide nanosheet through van der Waals interactions without formation of metal-chalcogen covalent bonds. A planar ligand plane of the metal-organic framework is oriented substantially parallel to the basal plane of the 1T′-phase nanosheet.

In one embodiment, the transition-metal dichalcogenide nanosheet includes WS₂, MoS₂, MoSe₂, WSe₂, TiS₂, TiSe₂, TaS₂, TaSe₂, VS₂, VSe₂, NbS₂, NbSe₂, ReS₂, ReSe₂, or a mixed-chalcogenide analogue in a 1T′ phase.

In one embodiment, the metal-organic framework includes a coordination network formed from a multinuclear metal node and a planar π-conjugated ligand.

In one embodiment, the ligand is selected from HHTP, TCPP, HHB, HAB, HITP, HTTP, HHTN, HHTT, or functional derivatives thereof.

In one embodiment, a metal center of the metal-organic framework comprises Cu, Ni, Co, Fe, Mn, Zn, Rh, or a combination thereof.

In one embodiment, the metal-organic framework includes a mixed-metal center in which at least two different metal ions occupy coordination sites within a single ligand framework.

In one embodiment, the metal-organic framework forms a two-dimensional nanosheet morphology. In another embodiment, the metal-organic framework forms a one-dimensional nanorod morphology.

In one embodiment, the metal-organic framework is distributed across the basal plane of the nanosheet with an orientation deviation of less than 3 degrees across a lateral distance of at least 5 nm.

In one embodiment, the metal-organic framework exhibits an in-plane lattice periodicity that is commensurate with a surface lattice periodicity of the 1T′-phase nanosheet, such that corresponding crystallographic planes of the metal-organic framework and the 1T′-phase nanosheet are aligned in a fixed epitaxial orientation as observed by selected-area electron diffraction, while allowing a lattice spacing deviation of less than 10 percent attributable to van der Waals epitaxial accommodation.

In a second aspect, the present invention provides a method for forming a van der Waals epitaxial heterostructure. The method includes preparing a transition-metal dichalcogenide nanosheet in a metastable 1T′ phase; dispersing the transition-metal dichalcogenide nanosheet in a liquid medium to form a colloidal suspension; introducing a metal precursor and a planar π-conjugated ligand into the colloidal suspension; and allowing the metal precursor and ligand to coordinate on a basal surface of the transition-metal dichalcogenide nanosheet to form a metal-organic framework that adopts an epitaxial crystallographic orientation aligned with a nanosheet lattice through van der Waals interactions.

In one embodiment, the 1T′-phase nanosheet is prepared by electrochemical intercalation using a quaternary ammonium cation.

In one embodiment, the quaternary ammonium cation includes tetraethylammonium, tetrapropylammonium, tetraheptylammonium, tetradecylammonium, or a combination thereof.

In one embodiment, the planar π-conjugated ligand is selected from HHTP, TCPP, HITP, HTTP, HHB, HAB, or derivatives thereof.

In one embodiment, the metal precursor includes Cu²⁺, Ni²⁺, Co²⁺, Fe²⁺, Mn²⁺, Zn²⁺, Rh³⁺, or a combination thereof.

In one embodiment, the method further comprising cooling the metal-organic framework to a temperature between 0° C. and 15° C. during an initial nucleation period to regulate ligand-metal coordination kinetics.

In one embodiment, the planar π-conjugated ligand in the reaction medium has a concentration in a range of 0.01 to 10 mg mL⁻¹.

In one embodiment, which is the Cu₃HHTP₂ MOF, the metal precursor and the planar π-conjugated ligand have a molar ratio of 3:_2.

In one embodiment, the coordination reaction is carried out for a duration of 0.5-72 hours to allow oriented metal-organic framework growth on the basal plane of the nanosheet.

In one embodiment, the liquid medium includes water and an organic solvent selected from DMF, IPA, ethanol, acetonitrile, or mixtures thereof.

The vdW epitaxial interface formed according to the present invention imparts significant functional advantages. For example, the Cu-HHTP/1T′-WS₂ heterostructure exhibits a remarkably high EMW absorption performance, achieving a minimum reflection loss of −89.8 dB, which is superior to previously reported non-magnetic EMW absorbing materials. The controlled epitaxial interface enhances dielectric loss, optimizes impedance matching, and enables strong interfacial polarization, thereby contributing to the exceptional absorption capability.

The invention therefore enables new opportunities for designing high-efficiency EMW absorbing materials and for advancing applications in electromagnetic pollution mitigation, electronics, catalysis, and other fields requiring tailored organic/inorganic interfaces.

### BRIEF DESCRIPTION OF THE DRAWINGS

Embodiments of the invention are described in more details hereinafter with reference to the drawings, in which:

FIG. 1A depicts a schematic illustration of a general preparation strategy for forming metal-organic framework/transition-metal dichalcogenide (MOF/TMD) van der Waals epitaxial heterostructures according to the present invention. FIG. 1B depicts a schematic illustration of a wet-chemical process for preparing a Cu-HHTP MOF (denoted as Cu-M in the following figures)/1T′-WS₂ van der Waals epitaxial heterostructure:

FIG. 2A depicts a scanning electron microscopy (SEM) image of 1T′-WS₂ nanosheets. FIG. 2B depicts an atomic force microscopy (AFM) image of the 1T′-WS₂ nanosheets with measured thickness values indicated thereon. FIG. 2C depicts a thickness distribution histogram of the 1T′-WS₂ nanosheets obtained from the AFM image of FIG. 2B. FIG. 2D depicts a transmission electron microscopy (TEM) image of the obtained 1T′-WS₂ nanosheets. FIG. 2E depicts a corresponding selected-area electron diffraction (SAED) pattern of the 1T′-WS₂ nanosheets. FIG. 2F depicts an aberration-corrected high-angle annular dark-field scanning transmission electron microscopy (HAADF-STEM) image of a typical 1T′-WS₂ nanosheet. FIG. 2G depicts a fast Fourier transform (FFT) pattern corresponding to FIG. 2F. FIG. 2H depicts a W 4f X-ray photoelectron spectroscopy (XPS) spectrum of the prepared 1T′-WS₂ nanosheets.

FIG. 3 depicts a HAADF-STEM image of a 1T′-WS₂ nanosheet, and a line-scan intensity profile obtained from the dotted line, showing the shortest W—W atomic distance;

FIG. 4A depicts a low-dose high-resolution transmission electron microscopy (HRTEM) image of a Cu-M/1T′-WS₂ heterostructure. FIG. 4B depicts a corresponding FFT pattern of FIG. 4A. FIG. 4C depicts an enlarged FFT pattern obtained from the dashed square region of FIG. 4B. FIG. 4D depicts an absolute-value-filtered HRTEM image obtained from the dashed square region of FIG. 4A. FIG. 4E depicts an enlarged absolute-value-filtered HRTEM image obtained from the dashed square region of FIG. 4D. FIG. 4F depicts a corresponding atomic structure model of the Cu-M/1T′-WS₂ heterostructure;

FIG. 5A depicts an atomic structure model of 1T′-WS₂. FIG. 5B depicts an atomic structure model of Cu-M. FIG. 5C depicts an atomic structure model of the synthesized Cu-M/1T′-WS₂ heterostructure. FIG. 5D depicts an enlarged FFT pattern corresponding to the heterostructure;

FIG. 6A depicts a large-scale TEM image of a Cu-M/1T′-WS₂ heterostructure. FIG. 6B depicts a corresponding SAED pattern. FIG. 6C depicts an enlarged SAED pattern of FIG. 6B. FIG. 6D depicts a TEM image and corresponding FFT pattern of the Cu-M/1T′-WS₂ heterostructure. FIG. 6E depicts energy-dispersive spectroscopy (EDS) elemental mapping images of the Cu-M/1T′-WS₂ heterostructure. FIG. 6F depicts a calculated binding energy of an HHTP ligand adsorbed on a 1T′-WS₂ surface in a face-on and edge-on orientation. FIG. 6G depicts an energy difference of the HHTP ligand adsorbed on the 1T′-WS₂ surface at different rotation angles;

FIG. 7A depicts a height distribution of Cu-M domains on 1T′-WS₂. FIG. 7B depicts a lateral size distribution of the Cu-M domains on 1T′-WS₂;

FIG. 8A depicts a Cu K-edge X-ray absorption near-edge structure (XANES) spectrum of Cu-M/1T′-WS₂, Cu-M, CuO, Cu₂O, and Cu foil. FIG. 8B depicts Fourier-transformed extended X-ray absorption fine structure (FT-EXAFS) spectra of the same samples. FIG. 8C depicts experimental and fitted Cu K-edge FT-EXAFS spectra of Cu-M/1T′-WS₂ and Cu-M. FIG. 8D depicts Cu XPS spectra of Cu-M/1T′-WS₂ and Cu-M. FIG. 8E depicts Raman spectra of Cu-M/1T′-WS₂, Cu-M, and HHTP. FIG. 8F depicts Fourier-transform infrared (FTIR) spectra of Cu-M/1T′-WS₂, Cu-M, and HHTP;

FIG. 9 depicts Cu K-edge wavelet-transformed EXAFS spectra of Cu-M/1T′-WS₂ and Cu-M;

FIG. 10 depicts Cu K-edge wavelet-transformed EXAFS spectra of CuO, Cu₂O, and Cu foil;

FIG. 11 depicts W XPS spectra of the Cu-M/1T′-WS₂ heterostructure with corresponding deconvoluted fitting curves;

FIG. 12A depicts a Raman spectrum of Cu-M/1T′-WS₂. FIG. 12B depicts an enlarged Raman spectrum of Cu-M/1T′-WS₂;

FIG. 13A depicts a TEM image of a Cu-M/1T′-WS₂ physical mixture. FIG. 13B depicts a Cu XPS spectrum of the mixture. FIG. 13C depicts a W XPS spectrum of the mixture;

FIG. 14A depicts a real part (μ′) of magnetic permeability of Cu-M/1T′-WS₂, Cu-M/1T′-WS₂-mix, 1T′-WS₂, and Cu-M. FIG. 14B depicts an imaginary part (μ″) of magnetic permeability of the same samples;

FIG. 15A depicts a real part of permittivity (ε′). FIG. 15B depicts an imaginary part of permittivity (ε″). FIG. 15C depicts dielectric loss tangents. FIG. 15D depicts attenuation coefficients of the indicated samples. FIG. 15E depicts calculated conduction loss. FIG. 15F depicts calculated polarization loss. FIG. 15G depicts three-dimensional reflection loss values.

FIG. 15H depicts corresponding two-dimensional projections. FIG. 15I depicts two-dimensional impedance matching projections;

FIG. 16 depicts electrical conductivities of the different samples;

FIG. 17A depicts impedance matching characteristics of 1T′-WS₂. FIG. 17B depicts three-dimensional reflection loss values of 1T′-WS₂. FIG. 17C depicts corresponding two-dimensional reflection loss projections. FIG. 17D depicts a two-dimensional projection of the reflection loss values of 1T′-WS₂ under different absorber thicknesses and operating frequencies;

FIG. 18A depicts impedance matching characteristics of Cu-M. FIG. 18B depicts three-dimensional reflection loss values of Cu-M. FIG. 18C depicts corresponding two-dimensional reflection loss projections. FIG. 18D depicts a two-dimensional projection of the reflection loss values of Cu-M under different absorber thicknesses and operating frequencies;

FIG. 19 depicts Cole-Cole plots of Cu-M/1T′-WS₂ and Cu-M/1T′-WS₂-mix;

FIG. 20A depicts a top view and side view of a DFT model of Cu-M/1T′-WS₂. FIG. 20B depicts an interfacial charge distribution of Cu-M/1T′-WS₂;

FIG. 21 depicts a simulated electric-field distribution of Cu-M/1T′-WS₂;

FIG. 22 depicts reflection loss values of Cu-M/1T′-WS₂ at various absorber thicknesses;

FIG. 23A depicts impedance matching characteristics of Cu-M/1T′-WS₂-mix. FIG. 23B depicts three-dimensional reflection loss values. FIG. 23C depicts corresponding two-dimensional projections;

FIG. 24 depicts schematic crystal structures of 1T′-WS₂ and a Cu-HHTP metal-organic framework;

FIG. 25 depicts Raman spectra of the obtained 1T′-WS₂ nanosheets and Cu-HHTP/1T′-WS₂ heterostructures;

FIG. 26A depicts a TEM image of a Cu-HHTP/1T′-WS₂ heterostructure. FIG. 26B depicts a SAED pattern. FIG. 26C depicts an EDS elemental mapping image. FIG. 26D depicts an HRTEM image. FIG. 26E depicts a high-magnification SAED pattern;

FIG. 27A depicts a TEM image of a Cu-HHTP/1T′-MoS₂ heterostructure. FIG. 27B depicts a SAED pattern. FIG. 27C depicts an EDS elemental mapping image. FIG. 27D depicts an HRTEM image. FIG. 27E depicts a high-magnification SAED pattern;

FIG. 28 depicts schematic crystal structures of 1T′-WS₂ and a Cu-TCPP metal-organic framework;

FIG. 29A depicts a TEM image of a Cu-TCPP/1T′-WS₂ heterostructure. FIG. 29B depicts a SAED pattern. FIG. 29C depicts an HRTEM image. FIG. 29D depicts EDS elemental mapping images;

FIG. 30 depicts a top view and a side view of the obtained Cu-TCPP/1T′-WS₂ heterostructure;

FIG. 31 depicts single-atomic metal sites in a TCPP metal-organic framework; and

FIG. 32A depicts a TEM image of a Cu—Ni-TCPP/1T′-WS₂ heterostructure. FIG. 32B depicts a SAED pattern. FIG. 32C depicts a high-magnification SAED pattern. FIG. 32D depicts an HRTEM image. FIG. 32E depicts EDS elemental mapping images.

### DETAILED DESCRIPTION

In the following description, metal-organic frameworks/transition metal dichalcogenides vdW epitaxial heterostructures and synthetic methods to fabricate MOF/TMD vdW heterostructure are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

Heterostructures formed by combining materials with different chemical compositions, lattice structures, or electronic properties can exhibit synergistic performance enhancements in various applications. vdW integration, in which prefabricated building blocks are assembled through vdW interactions rather than covalent bonds, eliminates lattice-matching requirements and enables broad flexibility in material compositions, structures, and physicochemical properties. Although vdW integration allows the construction of artificial heterostructures and superlattices with atomically clean and electronically sharp interfaces, the absence of covalent bonding makes it difficult to precisely control the growth orientation between the components, and large-scale fabrication of epitaxial vdW heterostructures remains challenging. Furthermore, conventional transition-metal dichalcogenide (TMD) composites predominantly exist in the thermodynamically stable 2H phase or mixed 2H/1T/1T′ phases, which further limits their electromagnetic wave absorption performance and constrains mechanistic investigations.

Accordingly, the present invention provides a facile and general approach to prepare a series of organic/inorganic vdW heterostructures. By using an optimized organic molecule-assisted electrochemical intercalation and exfoliation method, 1T′-TMDs nanosheets, such as 1T′-MoS₂ and WS₂ are provided. Afterwards, the growth of MOF nanostructures on 1T′-TMD NSs is conducted through a wet-chemical method by using various metal salts and organic ligands as precursors, and the as-prepared 1T′-TMD NSs as templates. It can achieve the epitaxy growth of the MOF on the two-dimensional transition metal dichalcogenides with unconventional phase (e.g., 1T′-TMDs nanosheets), forming a series of MOF/TMD heterostructures. It is the first time in the world to epitaxial grow the MOF on TMD templates. All the preparation processes can be conducted at ambient conditions which makes it compatible for scale-up for practical application in the future.

Through this strategy, a large variety of MOF can be grown on different 1T′-TMD NSs to form a series of unprecedented vdW MOF/1T′-TMD heterostructures. A high degree of control over the composition and structure of the vdW MOF/1T′-TMD heterostructures can be prepared, such as M-HHTP/1T′-MoS₂, M-HHTP/1T′-WS₂, M-HHTP/1T′-MoSe₂, M-HHTP/1T′-WS₂, M-HITP/1T′-MoS₂, M-HITP/1T′-WS₂, M-HITP/1T′-MoSe₂, M-HITP/1T′-WSe₂, M-TCPP-N/1T′-MoS₂, M-TCPP-N/1T′-WS₂, M-TCPP-N/1T′-MoSe₂, M-TCPP-N/1T′-WSe₂, and so on (M refers to Ni, Co, Cu, Zn, Fe, Mn, Al, Rh, etc., N refers to Ni, Co, Cu, Zn, Pt, Pd, etc.), showing the universality of the synthetic strategy. HHTP refers to 2,3,6,7,10,11-hexahydroxytriphenylene. TCPP=tetrakis(4-carboxyphenyl) porphyrin).

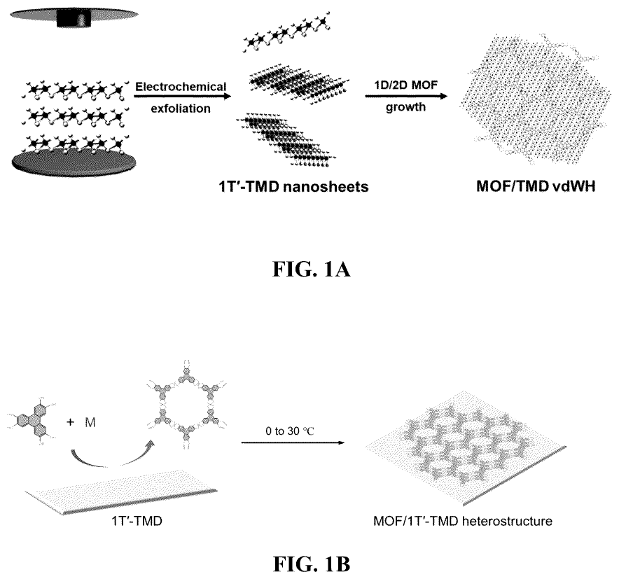

In certain embodiments, FIGS. 1A and 1B illustrate an exemplary strategy for preparing the van der Waals MOF/TMD heterostructures disclosed in the present invention. As shown in FIG. 1A, the process begins with the electrochemical exfoliation of a bulk transition metal dichalcogenide precursor to obtain high quality metastable 1T′-phase nanosheets that serve as atomically thin crystalline templates. Upon introduction of planar organic ligands and metal precursors under controlled solution phase conditions, oriented nucleation occurs on the basal plane of the TMD nanosheets, followed by continued coordination driven growth that produces one dimensional (1D) or two dimensional (2D) MOF domains aligned with the underlying lattice through van der Waals interactions.

FIG. 1B further illustrates the interfacial assembly mechanism at the molecular level. In this schematic, individual conjugated ligands coordinate with metal ions to form a planar MOF unit, which subsequently adsorbs onto the TMD basal plane through π-surface interactions. Continued lateral propagation of these units yields an ordered MOF lattice that conforms to the crystallographic registry of the TMD substrate without requiring covalent bonding or lattice matching. This cooperative ligand adsorption and in plane framework growth enables uniform epitaxy, precise control over interfacial orientation, and the formation of structurally coherent organic or inorganic heterostructures.

In one embodiment, the present invention provides a class of organic-inorganic van der Waals epitaxial heterostructures in which a metal-organic framework is grown directly on a transition-metal dichalcogenide nanosheet in a metastable 1T′ phase. Unlike conventional approaches that rely on mechanical stacking, drop-casting, or random adsorption of metal-organic frameworks on two-dimensional materials, the disclosed method enables the formation of a crystallographically aligned interface in the absence of covalent bonding. The noncovalent yet highly ordered epitaxy enables structural registry between the metal-organic framework lattice and the basal plane of the 1T′-phase nanosheet, giving rise to interfacial behaviors that are not attainable through physical mixtures or non-epitaxial composites.

In one embodiment, the transition-metal dichalcogenide nanosheet comprises WS₂, MoS₂, MoSe₂, WSe₂, TiS₂, TiSe₂, TaS₂, TaSe₂, VS₂, VSe₂, NbS₂, NbSe₂, ReS₂, ReSe₂, or a mixed-chalcogenide derivative prepared or stabilized in the 1T′ phase. The metastable 1T′ phase provides an atomically flat, coordinatively unsaturated basal surface that is highly distinct from the thermodynamically favored 2H phase commonly used in the prior art. In certain embodiments, the 1T′ phase is obtained by electrochemical intercalation of a quaternary ammonium cation such as tetraethylammonium, tetrapropylammonium, tetraheptylammonium, or tetradecylammonium. The intercalation process results in expanded interlayer spacing, improved exfoliation efficiency, and exposure of a clean, distortion-stabilized octahedral coordination environment that promotes epitaxial interactions with planar conjugated ligands.

In one embodiment, the metal-organic framework comprises a coordination network formed from multinuclear metal nodes and a planar-conjugated organic ligand. Suitable ligands include HHTP, TCPP, HHB, HAB, HITP, HTTP, HHTN, HHTT, and functional equivalents thereof. Exemplary metal centers include Cu, Ni, Co, Fe, Mn, Zn, Rh, and combinations thereof. In certain embodiments, the metal-organic framework comprises a mixed-metal center in which two or more metal ions occupy coordination sites within a single ligand framework, enabling uniform distribution of heterometallic nodes across the epitaxial interface. The use of planar conjugated ligands provides both extended π-surfaces and periodic coordination geometries that promote alignment with the periodicity of the underlying 1T′-phase nanosheet.

In one embodiment, the planar ligand plane of the metal-organic framework is oriented substantially parallel to the basal plane of the TMD nanosheet. This geometric relationship enables adsorption-guided epitaxial nucleation and supports long-range propagation of crystallographic alignment across lateral dimensions exceeding several hundred nanometers. The epitaxial relationship may be confirmed by selected-area electron diffraction, where diffraction spots corresponding to the metal-organic framework and the 1T′-phase nanosheet exhibit fixed angular registry. In some embodiments, the deviation in domain-to-domain orientation across the nanosheet is less than a predetermined threshold, thereby demonstrating coherent epitaxy across multiple metal-organic framework domains.

In one embodiment, the disclosed strategy supports multiple metal-organic framework morphologies, including two-dimensional nanosheets and one-dimensional nanorods. The ability to obtain both morphologies from the same underlying epitaxial mechanism provides enhanced structural generality and supports broader claim scope. In certain embodiments, the in-plane lattice spacing of the metal-organic framework matches a corresponding periodicity of the nanosheet within a defined deviation, enabling a van der Waals epitaxial interface despite nominal lattice mismatches exceeding 10-20 percent. Such tolerance to lattice mismatch contrasts sharply with conventional inorganic epitaxy, which typically requires mismatch below 5 percent, and represents one of the unexpected and advantageous features of the present invention.

In one embodiment, the epitaxial interface exhibits a spatial distribution of electron density consistent with interfacial charge displacement between the metal-organic framework and the 1T′-phase nanosheet. The charge redistribution may be confirmed by theoretical modeling, X-ray absorption spectroscopy, or other spectroscopic techniques. In certain embodiments, the aligned contact between a conductive or semiconductive 1T′-phase nanosheet and a metal-organic framework containing extended π-ligand systems enables strong interfacial polarization under an alternating electromagnetic field. This structural and electronic behavior distinguishes the disclosed heterostructures from physically mixed or non-epitaxial materials, which do not exhibit the same degree of charge localization or polarization.

In one embodiment, the epitaxial heterostructure contains no detectable M-S covalent bonds at the interface, where M represents a metal center of the metal-organic framework. This absence of covalent bonding, confirmed by X-ray absorption and photoelectron spectroscopy, further supports the characterization of the interface as a van der Waals epitaxial junction rather than a chemically bonded composite.

In one embodiment, at least 50, 100, or 200 metal-organic framework domains exhibit identical crystallographic orientation on a single nanosheet. Such long-range ordering is uniquely enabled by the adsorption-guided nucleation mechanism and the inherent parallelism between the ligand plane and the basal surface of the 1T′-phase nanosheet.

Moreover, the present invention provides a method of forming a van der Waals epitaxial heterostructure, including preparing a transition-metal dichalcogenide nanosheet in a metastable 1T′ phase; dispersing the transition-metal dichalcogenide nanosheet in a liquid medium to form a colloidal suspension; introducing a metal precursor and a planar π-conjugated ligand into the colloidal suspension; and allowing the metal precursor and ligand to coordinate on a basal surface of the transition-metal dichalcogenide nanosheet to form a metal-organic framework that adopts an epitaxial crystallographic orientation aligned with a nanosheet lattice through van der Waals interactions.

In certain embodiments, nucleation is regulated by cooling the reaction mixture between 0° C. and 15° C. The ligand concentration, metal-to-ligand ratio, stirring rate, solvent composition, and reaction duration may each be controlled within specified ranges to promote epitaxial growth rather than random aggregation. The method accommodates water, DMF, ethanol, isopropanol, acetonitrile, or mixtures thereof as solvent systems. After nucleation, the reaction temperature may be increased to promote propagation of the epitaxial front across the basal plane.

In one embodiment, the electrochemical intercalation is carried out in a two electrode configuration at applied voltages between 3 V and 12 V, each voltage step being maintained for a duration between 5 minutes and 60 minutes until the transition-metal dichalcogenide crystals are fully intercalated.

In one embodiment, the intercalated electrode film is subjected to exfoliation by sonication in an organic solvent for a period between 10 seconds and 10 minutes while the container is maintained in an ice water bath, followed by centrifugation at a speed between 2,000 rpm and 10,000 rpm to isolate the 1T′-phase nanosheets.

In one embodiment, the colloidal suspension of the 1T′-phase nanosheets in the liquid medium has a nanosheet concentration in a range of 0.01 to 10 mg mL-1, for example 0.1 to 5 mg mL-1, so as to provide sufficient surface area for metal-organic framework growth while maintaining colloidal stability.

In one embodiment, the planar π-conjugated ligand in the reaction medium has a concentration in a range of 0.01 to 10 mg mL-1, for example 0.05 to 2 mg mL-1, and the metal precursor is introduced at a molar ratio of metal precursor to ligand in a range of 0.1:1 to 5:1.

In one embodiment, the liquid medium comprises a mixture of water and an organic solvent in a volume ratio within a range of 1:9 to 9:1, the organic solvent being selected from N,N-dimethylformamide, isopropanol, ethanol, acetonitrile, or mixtures thereof.

In one embodiment, the nanosheet suspension is maintained under stirring at a rate between 200 rpm and 1,000 rpm during nucleation and growth of the metal-organic framework so as to maintain a uniform distribution of nanosheets and precursors in the reaction volume.

In one embodiment, the coordination reaction between the metal precursor and the planar π-conjugated ligand is conducted for a duration between 1 hour and 48 hours, for example between 4 hours and 24 hours, to allow the metal-organic framework to develop an epitaxial crystallographic orientation on the basal plane of the nanosheet.

In one embodiment, the reaction mixture is cooled to a temperature between 0° C. and 15° C. during an initial nucleation period lasting between 0.5 hour and 6 hours, and is then maintained at a temperature between 15° C. and 60° C. during a subsequent growth period to promote oriented framework growth.

In one embodiment, the as formed metal-organic framework coated nanosheets are collected by centrifugation at a speed between 5,000 rpm and 15,000 rpm for a duration between 5 minutes and 30 minutes, followed by at least one washing step with an organic solvent and at least one washing step with water to remove unreacted precursors and free ligand.

In one embodiment, the mass ratio of the metal-organic framework to the 1T′-phase nanosheet in the van der Waals epitaxial heterostructure is adjusted within a range of 0.5:1 to 10:1, for example 1:1 to 5:1, by varying at least one of the ligand concentration, metal precursor concentration, or reaction time.

The following embodiments further illustrate the compatibility of the disclosed epitaxial mechanism with different metal-organic frameworks, different transition-metal dichalcogenides, and different metal-node compositions, including Cu-HHTP nanosheets, Cu-HHTP nanorods, Cu-TCPP nanosheets, Ni-TCPP nanosheets, and mixed-metal Cu—Ni-TCPP nanosheets grown on 1T′-WS₂ or 1T′-MoS₂ templates. These embodiments collectively demonstrate the generality and scalability of the disclosed van der Waals epitaxial strategy and establish its applicability to a broad class of metal-organic frameworks and metastable TMD structures.

### EXAMPLE

### Example 1—Materials and Methods

### Chemicals

Tungsten disulfide (WS₂, 99.8%) was purchased from Alfa Aesar (USA). Potassium oxalate monohydrate (K₂C₂O₄·H₂O, 99.8%), Copper acetylacetonate (Cu(acac)₂, 97%) and Cupric acetate anhydrous (Cu(CH₃COO)₂, 99.99%) were purchased from Aladdin (China). Sulfur powder (S, 99.5%), Acetic acid (AA, 99.99%), poly(vinylidene fluoride) (PVDF), acetonitrile (CH₃CN), N,N-dimethylformamide (DMF), isopropanol and ethanol (absolute) were purchased from Sigma-Aldrich. Tetraheptylammonium bromide (THAB) and 2,3,6,7,10,11-Hexahydroxytriphenylene (HHTP, 95.0%) were purchased from Tokyo Chemical Industry Co., Ltd (Tokyo, Japan). Ultra-high purity (99.999%) H₂ and Ar were purchased from Linde HKO Limited (Hong Kong, China). Copper (Cu) foils were purchased from ACME Research Support Pte Ltd (Singapore). All chemicals and materials were used as received without any further purification. The Milli-Q water with a resistivity of 18.2 MΩ·cm (Milli-Q System, Millipore, Billerica, MA, USA) was used in all experiments.

Synthesis of KₓWS₂ Crystals

250 mg of WS₂ powder were mixed with 200 mg of K₂C₂O₄·H₂O and 320 mg of S powder, which were ground for 15 min in an agate mortar. The mixture was transferred to an alumina crucible and then placed at the center of a quartz tube. After being vacuumed and then refilled with pure Ar for three times, the quartz tube was purged with a mixed gas flow of H₂ (30 sccm) and Ar (70 sccm) for 15 min. Subsequently, the quartz tube was placed into a tube furnace which was preheated at 800° C., and then maintained at 800° C. for 4 h. After cooling down to room temperature, the obtained powder was collected and washed with Milli-Q water until the pH value of the suspension reached 7-8. Afterwards, the obtained powder was then stored in Milli-Q water for 24 h. After washing with Milli-Q water again and drying at room temperature under vacuum, the KxWS2 crystals were obtained and collected for further usage.

### Characterizations

Ultralow-dose high-resolution transmission electron microscopy (HRTEM) was performed on a Titan 80-300 microscope equipped with an image Cs corrector, operated at 300 kV. Spherical aberration (Cs) values were corrected to be in a range of ±5 μm. Specimen searching and pre-focusing were conducted with a dose rate of ~0.01 e/Å²/s. HRTEM images were acquired at a magnification of 55 k or 87 k by a Gatan K2 direct-detection camera in the electron-counting mode with the dose fractionation function. Electron diffraction patterns were collected using a Gatan Ultra-scan CCD camera. Transmission electron microscopy (TEM) and high-resolution TEM (HRTEM) images, selected area electron diffraction (SAED) patterns, scanning transmission electron microscopy (STEM) images, and the corresponding energy-dispersive X-ray spectroscopy (EDS) data were recorded on JEOL JEM-2100F (JEOL, Tokyo, Japan) at an acceleration voltage of 200 kV. Scanning electron microscope (SEM) images were recorded on a QUATTROS SEM system (Thermo Fisher Scientific). Atomic force microscopy (AFM) images were captured using a Bruker Dimension 5000 AFM under tapping mode. X-ray photoelectron spectroscopy (XPS) measurements were carried out on a VG ESCALAB 220I-XL system. Fourier transform infrared (FTIR) spectroscopy data were obtained on a Nicolet 6700 spectrometer. Raman spectra were recorded with a Renishaw in Via™ conformal Raman microscope with an excitation wavelength of 532 nm and a low power density of <5 mW/um² to avoid the phase transition of the 1T′-WS₂. The X-ray absorption data at the Cu K-edge of the samples were recorded at room temperature in transmission mode using ion chambers at beam line BL14W1 of the Shanghai Synchrotron Radiation Facility (SSRF), China. The station was operated with a Si(111) double crystal monochromator. During the measurement, the storage ring was operated at energy of 3.5 GeV and a current of 220 mA (top-up). The photon energy was calibrated with the first inflection point in Cu K-edge of Cu metal foil, respectively. Processing and analysis of data were carried out on Athena and Artemis (version 0.9.26).

### Electromagnetic Characterization

To measure the electromagnetic parameters, the powdery samples (22.5 wt. %) were mixed with liquid paraffin under heating. The mixtures were subsequently solidified by cooling and then pressed into ring-shaped samples with an outer diameter of 3.04 mm and an inner diameter of 7.00 mm for electromagnetic parameters tests. All the electromagnetic parameters were measured by a vector network analyzer (VNA, Keysight E5080B) in the coaxial method. For electrical conductivity measurement, the powdery samples with paraffin were first compressed into a dense circular pellet (diameter=12 mm) under a 5-ton force using a hydraulic press in a mold and then tested via the four-point probe method (HELPASS HPS2662).

### Reflection Loss (RL) and Effective Absorption Bandwidth (EAB)

The RL was determined using transmission line and metal backplate theory. The governing equations are provided below:

$${Z}_{i n} = {{Z}_{0} ( \frac{{μ}_{r}}{{ε}_{r}} )}^{\frac{1}{2}} tanh [ j \frac{2 π fd}{c} {( {ε}_{r} {μ}_{r} )}^{\frac{1}{2}} ] \qquad equation 1$$

$$RL = 20 log \text{?} \frac{{Z}_{i n} - {Z}_{0}}{{Z}_{i n} + {Z}_{0}} \qquad equation 2$$

where Zᵢₙ denotes the input impedance, Z₀ is the free-space impedance, εᵣ (εᵣ=ε′−jε″), μᵣ (μᵣ=μ′−jμ″) are the complex permittivity and complex permeability measured by VNA test, j is the imaginary unit, f is the frequency of the EMW, d is the thickness of absorber, and c represents the velocity of light.

The RL values below −10 dB indicate that over 90% of the incident EMWs are absorbed. The frequency range over which the RL remains below −10 dB for a given thickness is defined as the EAB.

### Cole-Cole Plot and Dielectric Loss

Based on Debye relaxation theory, the real part (ε′) and the imaginary part (ε″) of the permittivity and the relationship between ε′ and ε″ can be expressed as follows:

$${ε}^{′} = {ε}_{∞} + \frac{{ε}_{s} - {ε}_{co}}{1 + {ω}^{2} {τ}^{2}} \qquad equation 3$$

$${ε}^{″} = {ε}_{p}^{″} + {ε}_{c}^{″} = ω τ \frac{{ε}_{s} - {ε}_{∞}}{1 + {ω}^{2} {τ}^{2}} \div \frac{σ}{{ε}_{0} ω} \qquad equation 4$$

where ε_{∞} and εₛ represent permittivity at electrostatic field and high-frequency limit, respectively. ε₀ refers to the permittivity of free space. ω is the angular frequency, τ is the polarization relaxation time, and σ is the electric conductivity. εₚ″ and ε_{c}″ represent the polarization loss and conductive loss, respectively.

Due to the nonnegligible conductivity, the original Debye formula should be modified as follows:

$${( {ε}^{′} - \frac{{ε}_{s} + {ε}_{∞}}{2} )}^{2} + {( {ε}^{″} - \frac{σ}{{ε}_{0} ω} )}^{2} = {( \frac{{ε}_{s} - {ε}_{∞}}{2} )}^{2} \qquad equation 5$$

Hence, Cole-Cole plots are displayed when plotting ε′ versus ε″, where each semicircle represents a polarization relaxation process, and the upward linear region represents the conduction loss. Dielectric loss consists of polarization loss and conduction loss, thus the contributions of polarization loss and conductive loss to dielectric loss can be estimated according to equation 4.

### Attenuation Coefficient (α) and Impedance Matching

Attenuation coefficient characterizes the EMWs absorption capacity and can be calculated by the following equation:

$$α = \frac{\sqrt{2} π f}{c} \times \sqrt{( {μ}^{″} {ε}^{″} - {μ}^{′} {ε}^{′} ) + \sqrt{{( {μ}^{″} {ε}^{″} - {μ}^{′} {ε}^{′} )}^{2} + {( {μ}^{′} {ε}^{″} + {μ}^{″} {ε}^{′} )}^{2}}} \qquad equation 6$$

Impedance matching is another key factor governing EMW absorption performance. The degree of impedance matching is commonly evaluated using the coefficient |Z|(|Z|=|Zᵢₙ/Z₀|). When |Z| is equal to 1, it means that all EMWs can enter the absorbers without reflection.

### Density Functional Theory (DFT) Calculation

The DFT calculations were conducted by using the Vienna ab initio simulation package (VASP). The D3 correction approach (DFT-D3) was employed in order to reflect the impact of vdW interactions. The energy cutoff for the plane wave basis expansion was set to 400 eV. Optimized structures were obtained by minimizing the forces on each ion using the conjugate gradient algorithm until they are below 0.05 eV/Å. The self-consistent calculations apply a convergence energy threshold of 10⁻⁵ eV. For the calculation of charge density difference, the monolayer Cu-M and 1T′-WS₂ model were constructed based on the experimental data. The charge density difference is defined by the formula:

$$Δρ = ρ ( Cu - M / 1 {T}^{′} - {WS}_{2} ) - ρ ( Cu - M ) - ρ ( 1 {T}^{′} - {WS}_{2} ) \qquad equation 7$$

in which ρ(Cu-M/1T′-WS₂), ρ(Cu-M) and ρ(1T′-WS₂) were the charge densities of the Cu-M/1T′-WS₂ heterostructure, monolayer Cu-M and monolayer 1T′-WS₂, respectively. The planar-averaged charge density difference Δρ(z) as a function of the coordinate z (along the normal direction of the Cu-M/1T′-WS₂ heterojunction interface) can be obtained by the integral of Δρ for the x-y plane.

The binding energy of the HHTP ligand to 1T′-WS₂ (Eb) was defined as:

$${E}_{b} = {E}_{s y s} - {E}_{H H T P} - {E}_{1 {T}^{′} - {WS}_{2}} , \qquad equation 8$$

in which, E_{sys}, E_{HHTP} and E_{1T′-WS}_{₂} are defined as the average potential energies of the HHTP/1T′-WS₂ system, HHTP ligand and 1T′-WS₂ substrate with a different geometry, respectively. Under this definition, a more-negative binding energy indicates a stronger interaction between HHTP and the substrate, i.e., 1T′-WS₂.

The energy different of the HHTP/1T′-WS₂ system (ΔE) with different rotation angles of the absorbed HHTP ligand was calculated as follows:

$$Δ E = {E}_{s y s} ( α ) - {E}_{s y s} ( 0 ° ) , \qquad equation 9$$

in which, E_{sys}(α) are defined as the total energy of the HHTP/1T′-WS₂ system with a HHTP rotation angle of α. The rotation angle α can be 0°, 20°, 40° and 60° respectively.

### Electric Field Distribution Simulation

The interfacial polarization behavior is illustrated through the simulation of electric field distribution using High Frequency Structure Simulator (HFSS). During the simulation, according to the data measured by SEM, the model sizes of Cu-M and 1T′-WS₂ were determined first. Then, the electromagnetic parameters were set according to the experimental data obtained by VNA. Finally, the driven solution frequency was set as 15 GHz.

### Example 2—Preparation of 1T′-WS₂ NSs by Electrochemical Intercalation

KₓWS₂ crystals and poly(vinylidene fluoride) (PVDF) were dispersed in N,N-dimethylformamide (DMF) at a mass ratio of 8:1:80 (KₓWS₂:PVDF:DMF). The resulting slurry was uniformly coated onto a copper (Cu) foil and dried under ambient conditions to form the cathode. A platinum (Pt) plate was used as the anode. Tetraheptylammonium bromide (THAB) was dissolved in acetonitrile at a concentration of 20 mg mL⁻¹ and served as the electrolyte. The electrochemical intercalation was performed in a two-electrode configuration. The applied voltages were sequentially set to 5 V, 7 V, and 10 V, each maintained for 20 minutes. Upon completion of intercalation, the electrode film was removed and transferred into a centrifuge tube containing 30 mL of DMF. The sample was then sonicated for 30 seconds while the centrifuge tube was immersed in ice water to minimize structural damage. The resulting dispersion was centrifuged at 8,000 rpm for 15 minutes, and the precipitate was collected. The precipitate was washed twice with DMF to remove residual electrolyte and impurities. Finally, the product was centrifuged at 2,000 rpm for 5 minutes to isolate the exfoliated 1T′-WS₂ nanosheets, which were collected for subsequent use.

The intercalation agent THAB can be changed to tetraethylammonium bromide (TEAB), tetrapropylammonium bromide (TPAB) and tetradecylammonium bromide (TDAB).

Other 1T′-TMD NSs, including 1T′-MoSe₂, 1T′-MoSₓSe₂₋ₓ, 1T′-MoS₂, 1T′-WSe₂ and 1T′-WS₂ₓSe₂₍₁₋ₓ₎, 1T′-MoₓW₁₋ₓS₂, MoₓW₁₋ₓSe₂, 1T′-MoₓW₁₋ₓS₂ₓSe₂₍₁₋ₓ₎, 1T′-MoTe₂, 1T′-WTe₂, 1T′-TiS₂, 1T′-TiSe₂, 1T′-TaS₂, 1T′-TaSe₂, 1T′-VS₂, 1T′-VSe₂, 1T′-NbS₂, 1T′-NbSe₂, 1T′-ReS₂, 1T′-ReSe₂ can be prepared by using the similar method.

### Example 3—Characterization of 1T′-WS₂ NSs as Catalyst Support

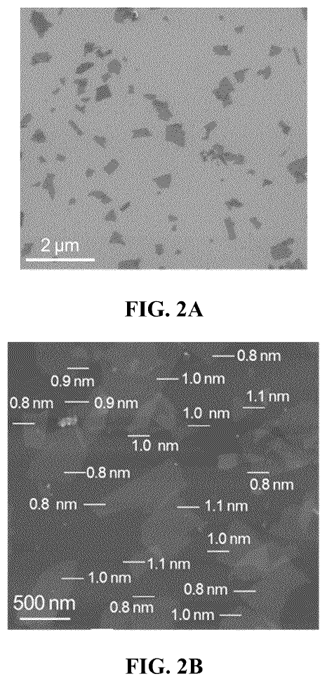

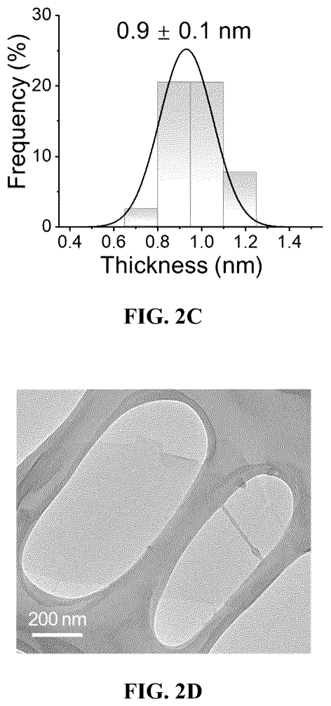

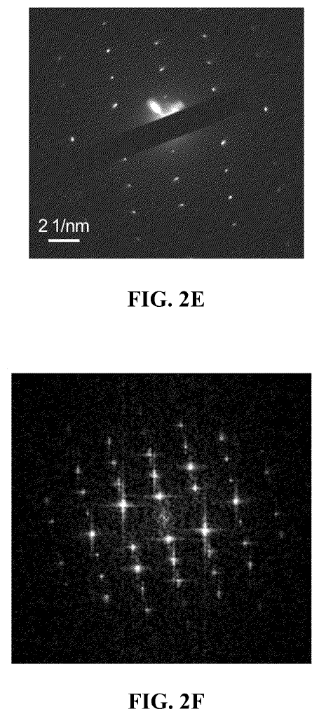

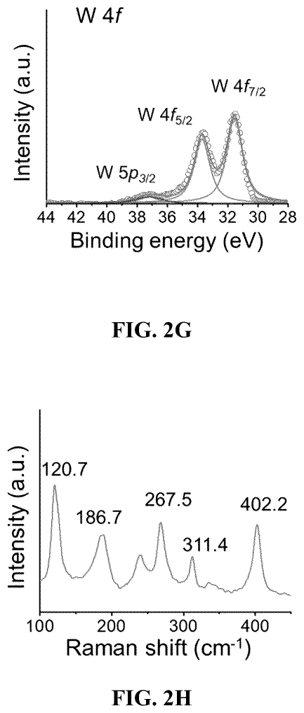

The structural characteristics of the exfoliated 1T′-WS₂ nanosheets (NSs) obtained through the optimized electrochemical intercalation and exfoliation procedure were examined. The resulting 1T′-WS₂ NSs exhibited lateral dimensions of several hundred nanometers (FIG. 2A) and a thickness of approximately 0.9±0.1 nm (FIGS. 2B-2C). The nanosheets possessed a clean, sheet-like morphology, as shown in FIG. 2D.

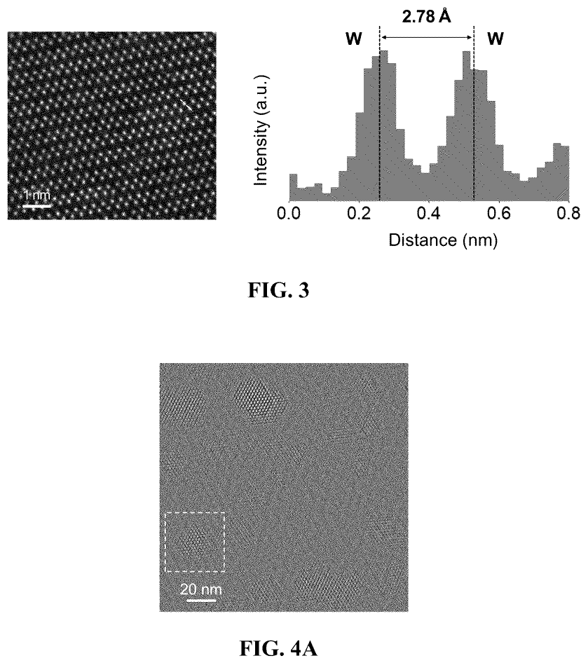

The SAED analysis of the nanosheets (FIG. 2E) revealed a distorted octahedral coordination pattern consistent with the 1T′ crystal structure, indicating high crystallinity. Aberration-corrected high-angle annular dark-field scanning transmission electron microscopy (HAADF-STEM) further confirmed the characteristic zigzag chain arrangement of the 1T′ phase, with the shortest W-W distance measured at 2.78 Å (FIG. 3). The corresponding fast Fourier transform (FFT) pattern (FIG. 2F) also verified the distorted octahedral structure, in agreement with theoretical 1T′-WS₂ models⁶.

X-ray photoelectron spectroscopy (XPS) analysis showed W 4f_{7/2} and W 4f_{5/2} peaks located at 31.5 eV and 33.7 eV, respectively (FIG. 2G), consistent with previously reported values for 1T′-WS₂⁶. Raman spectroscopy of the nanosheets (FIG. 2H) displayed five characteristic peaks at 120.7, 186.7, 267.4, 311.4, and 402.2 cm⁻¹, confirming the 1T′ phase. Notably, the E₂g¹ (350.7 cm⁻¹) and A₁g (420.5 cm⁻¹) modes of the 2H phase were absent, further demonstrating the high phase purity of the obtained 1T′-WS₂ NSs.

### Example 4—Growth of MOFs on 1T′-TMD Templates

The growth of MOFs on 1T′-TMD NSs is conducted through a wet-chemical method by using various metal salts and organic ligand as precursors, and the as-prepared 1T′-TMD NSs as templates.

Taking Cu as an example, the Cu-based precursors can be Copper (II) acetylacetonate (Cu(acac)₂), Copper (II) acetate, Cu(NO₃)₂, CuCl₂, CuSO₄ and many other cuprate. Cu can be replaced as Ni, Co, Zn, Fe, Mn, Rh, or any other metals.

The organic ligands can be 1,2,3,4,5,6-hexahydroxybenzene (HHB), 1, 2, 3, 4, 5, 6-hexaaminobenzene (HAB), HHTP, 2, 3, 6, 7, 10, 11-hexaiminotriphenylene (HITP), 2, 3, 6, 7, 10, 11-hexathioltriphenylene (HTTP), 2,3,7,8,12,13-hexahydroxytetraazanaphthotetraphene (HHTT), 2,3,8,9,14,15-hexahydroxytrinaphthylene (HHTN), TCPP and so on.

The 1T′-WS₂ can be changed as 1T′-MoSe₂, 1T′-MoSₓSe₂₋ₓ, 1T′-MoS₂, 1T′-WSe₂ and 1T′-WS₂ₓSe₂₍₁₋ₓ₎, 1T′-MoₓW₁₋ₓS₂, MoₓW₁₋ₓSe₂, 1T′-MoₓW₁₋ₓS₂ₓSe₂₍₁₋ₓ₎. The 1T′-WS₂ can also be changed as 2H-WS₂, 2H—MoS₂ and many other 2H-TMDs as well.

### Example 5—Preparation and Characterization of Cu-M/1T′-WS₂ Epitaxial Heterostructure

Cu-HHTP MOF (denoted Cu-M) was synthesized using a hydrothermal method⁴. Cu(CH₃COO)₂ (90.8 mg) was dissolved in 10 mL of water, and HHTP (97.3 mg) was dispersed in 10 mL of isopropanol (IPA). The aqueous Cu(CH₃COO)₂ solution was rapidly poured into the HHTP dispersion, and the mixture was heated at 85° C. for 900 minutes. The product was centrifuged (10,000 rpm), washed with ethanol and water, and freeze-dried.

To achieve epitaxial growth of Cu-M on 1T′-WS₂ nanosheets NSs, 5 μL of a 1T′-WS₂ dispersion in DMF (7 mg mL⁻¹ WS₂, quantified by ICP-OES) was redispersed into 2 mL of deionized water. A ligand solution was prepared by premixing 25 μL of HHTP in DMF (5 mg mL⁻¹) with 5 μL of ascorbic acid (AA, 0.1 vol percent). Subsequently, 50 μL of Cu(acac)₂ in DMF (2.5 mg mL⁻¹) together with the premixed HHTP/AA solution were injected into the 1T′-WS₂ dispersion in a 10-mL glass vial. The reaction vial was immersed in an ice-water bath during the first 4 hours to suppress rapid nucleation and facilitate oriented growth. The reaction was then continued at room temperature for 10 hours. The product was isolated by centrifugation at 10,000 rpm, washed three times with ethanol, and collected. ICP-OES analysis indicated a Cu-M:1T′-WS₂ mass ratio of approximately 2:1. The resulting epitaxial heterostructure is referred to as Cu-M/1T′-WS₂.

For comparison, pristine Cu-M was synthesized by a hydrothermal method. Specifically, 90.8 mg of Cu(CH₃COO)₂ was dissolved in 10 ml of water, and 97.3 mg of HHTP was dispersed in 10 mL of isopropanol (IPA). The aqueous Cu(CH₃COO)₂ solution was poured into the HHTP dispersion, and the mixture was kept at 85° C. for 900 minutes. The resulting solid was collected by centrifugation at 10,000 rpm, washed with ethanol and water, and then freeze-dried to obtain Cu-M powder. In addition, a physical mixture was prepared by combining Cu-M and 1T′-WS₂ in a mass ratio of 2:1, dispersing the mixture in ethanol, stirring for 24 hours, and then freeze-drying. This material is denoted as Cu-M/1T′-WS₂-mix.

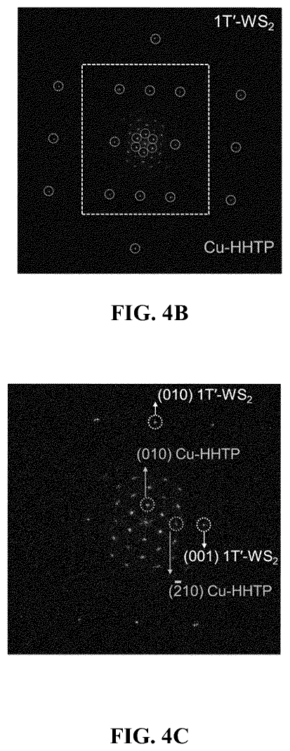

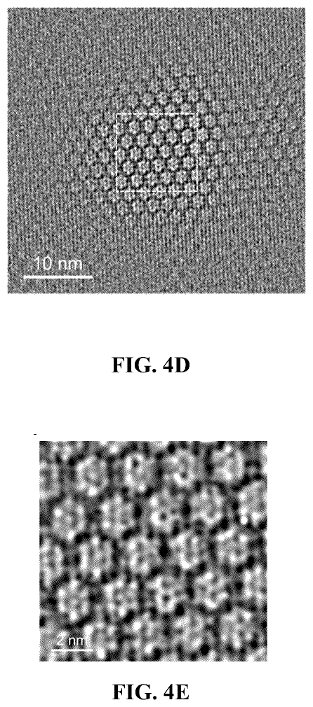

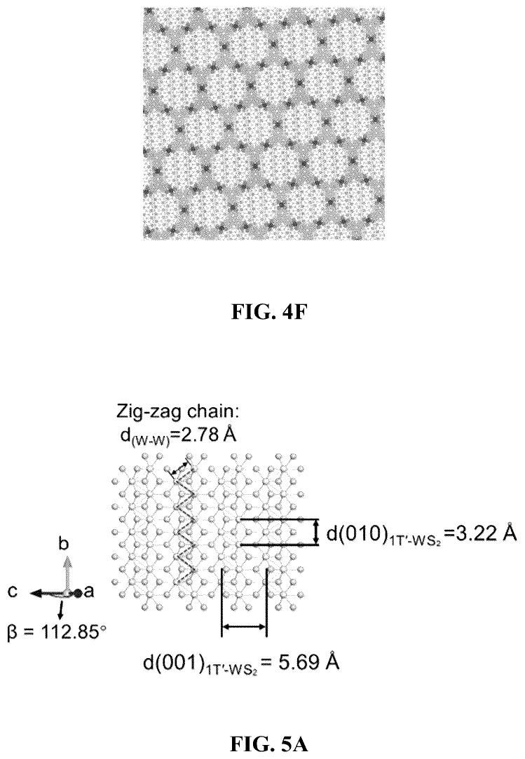

The structure and epitaxial nature of the Cu-M/1T′-WS₂ heterostructure were investigated by electron microscopy and diffraction. Low-dose high resolution transmission electron microscopy (HRTEM) images in FIG. 4A clearly show the hexagonal lattice of Cu-M, and all observed Cu-M domains exhibit the same orientation on the 1T′-WS₂ nanosheets. The measured lattice spacing of approximately 1.9 nm can be assigned to the {100} planes of Cu-M. The corresponding fast FFT patterns in FIG. 4B display two sets of diffraction spots, where the inner six spots enclosed by blue dotted circles are ascribed to the {100} planes of Cu-M and the outer spots enclosed by white dotted circles are attributed to the {001} planes of 1T′-WS₂. The enlarged FFT pattern in FIG. 4C reveals that the (010) plane of Cu-Mis aligned with the (010) plane of 1T′-WS₂ and that the (y̅210) plane of Cu-Mis aligned with the (001) plane of 1T′-WS₂.

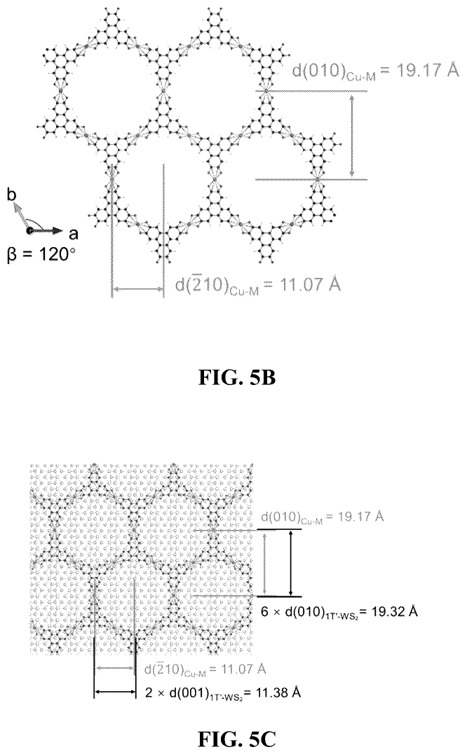

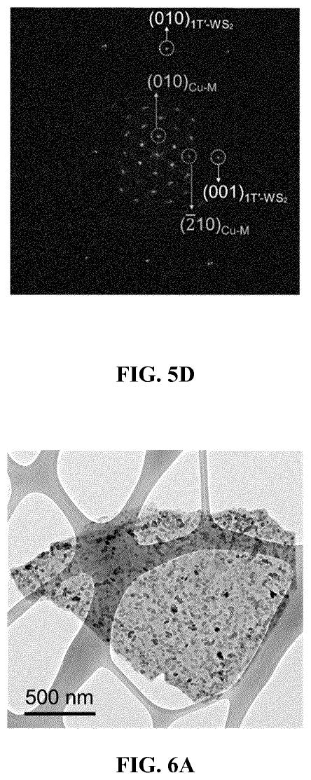

Based on this orientation relationship and DFT calculations, an atomic model of the Cu-M/1T′-WS₂ heterostructure was constructed in which the (001) planes of Cu-M are parallel to the (100) planes of the 1T′-WS₂ nanosheets (FIGS. 5A-5D), and the simulated structural model matches well with the enlarged HRTEM images in FIGS. 4D-4F.

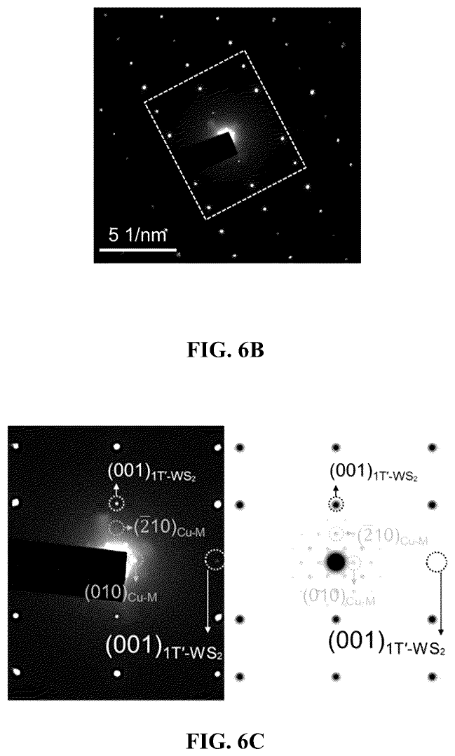

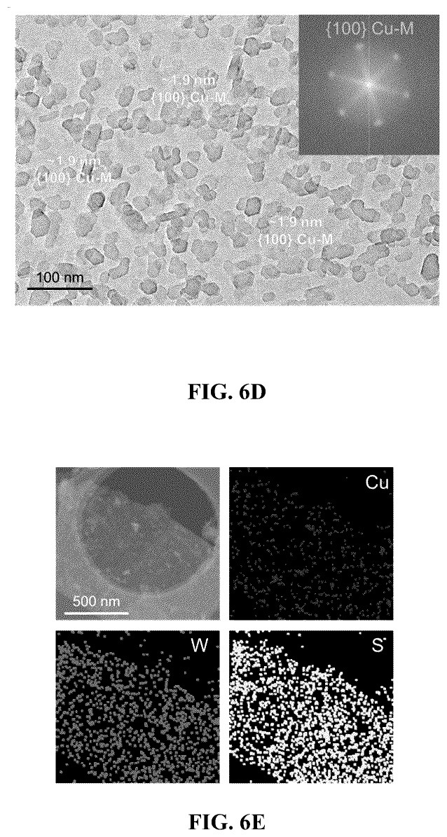

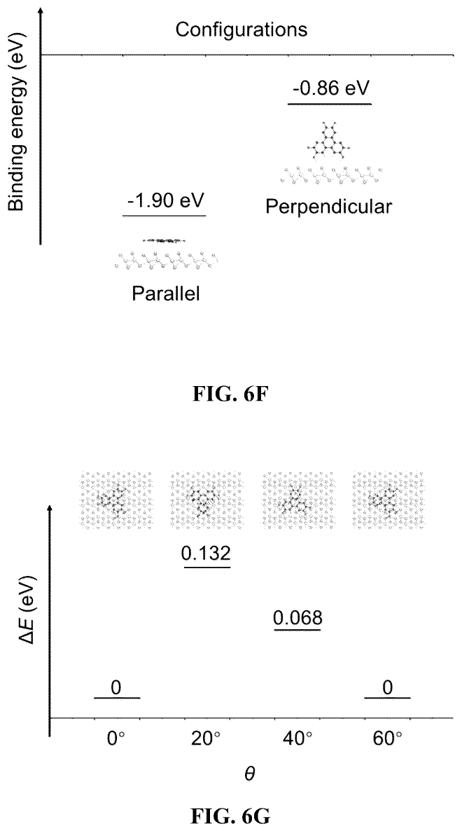

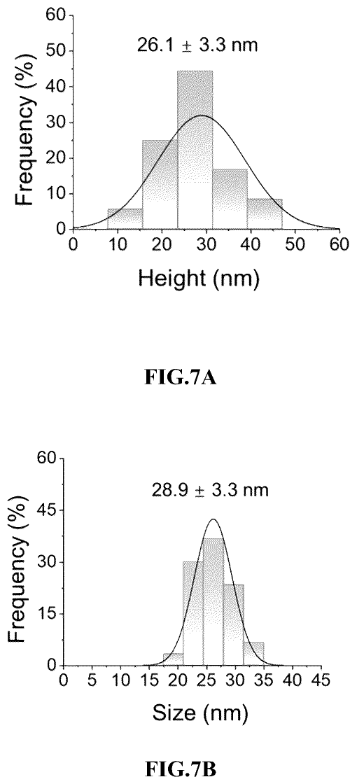

Large-area TEM analysis further supports the epitaxial relationship. As shown in FIG. 6A, hundreds of Cu-M nanostructures are observed on the 1T′-WS₂ nanosheets, and all of them display the same orientation, as confirmed by the SAED patterns in FIGS. 6B-6C. The SAED patterns again show two sets of diffraction spots that can be assigned to Cu-M and 1T′-WS₂, with no detectable change in the relative orientation between Cu-M and 1T′-WS₂ across the imaged region. The calculated SAED pattern based on the DFT model (FIG. 6C) is consistent with the experimental SAED patterns in FIGS. 6B-6C, which further confirms the epitaxial relationship between Cu-M and 1T′-WS₂. Statistical analysis indicates that the Cu-M nanostructures exhibit an average height of 26.1±3.3 nm and a lateral size of 28.9±3.3 nm (FIGS. 7A-7B). The TEM image in FIG. 6D shows that all Cu-M nanostructures exhibit the same hexagonal lattice and orientation, which is corroborated by the corresponding FFT pattern in the inset of FIG. 6D, and energy-dispersive X-ray spectroscopy (EDS) mapping in FIG. 6E demonstrates a uniform dispersion of Cu-M on the 1T′-WS₂ nanosheets.

DFT calculations, shown in FIG. 6F, were carried out to understand the epitaxial growth mechanism. The binding energies of HHTP ligands on the surface of 1T′-WS₂ were calculated for a parallel configuration, in which the ligand lies parallel to the 1T′-WS₂ surface, and a perpendicular configuration, in which the ligand stands nearly upright on the surface. The parallel adsorption exhibits a binding energy of −1.90 eV, which is significantly stronger than the −0.86 eV obtained for the perpendicular orientation. These results indicate that Cu-M preferentially grows with the (001) planes parallel to the basal planes of the 1T′-WS₂ nanosheets. Furthermore, FIG. 6G shows the energy difference between parallel-adsorbed HHTP ligands with different rotation angles, and the calculations demonstrate that a parallel HHTP ligand on 1T′-WS₂ with a rotation angle of 0° is the most energetically favorable arrangement, in agreement with the experimentally observed uniform orientation.

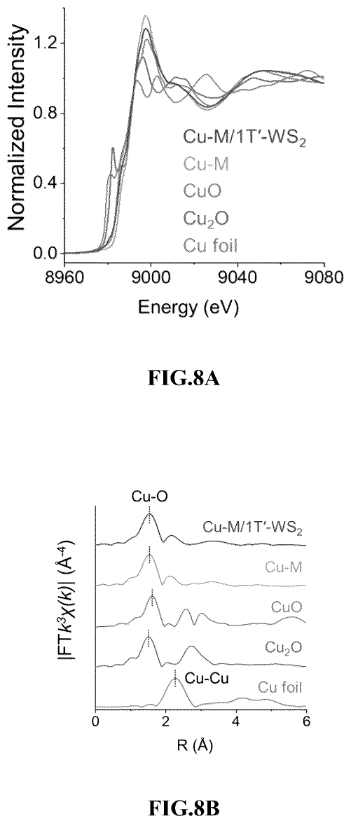

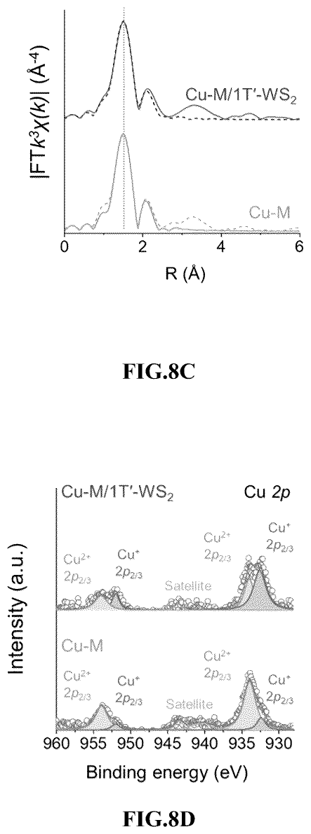

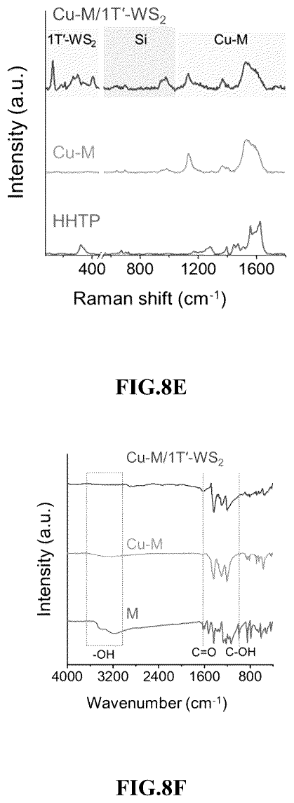

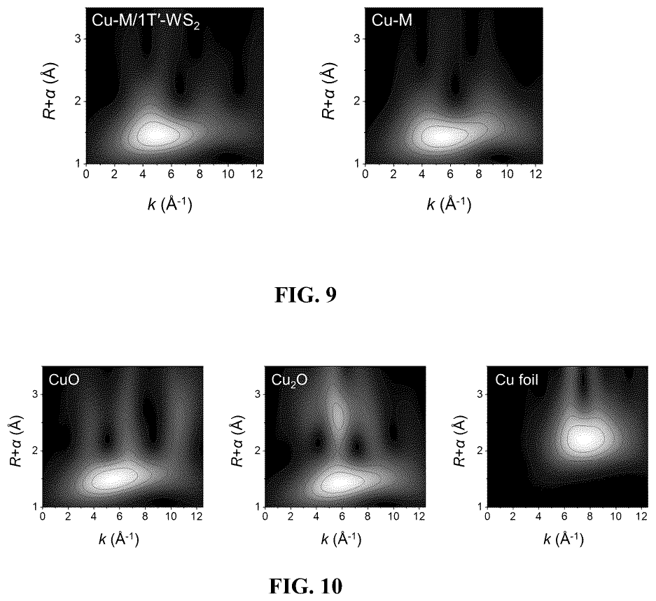

The electronic structure and coordination environment of Cu in the Cu-M/1T′-WS₂ heterostructure were further probed by X-ray absorption near-edge spectroscopy (XANES) and extended X-ray absorption fine structure (EXAFS) analysis. The Cu K-edge XANES spectrum in FIG. 8A indicates that Cu species in Cu-M/1T′-WS₂ exhibit a lower average oxidation state compared with CuO and pristine Cu-M. The Fourier-transformed Cu K-edge EXAFS spectrum of Cu-M/1T′-WS₂ in FIG. 8B shows a dominant peak at 1.53 Å, which can be attributed to Cu—O coordination. Fitting of the EXAFS data (FIG. 8C, Table 1) yields an average Cu—O bond length of 1.93 Å and an average coordination number of 4.7 in Cu-M/1T′-WS₂. These results are consistent with those of Cu-M, and no Cu—S peak is observed, indicating that the interaction between Cu-M and 1T′-WS₂ is governed by van der Waals forces rather than covalent Cu—S bonding. In addition, no Cu—Cu metallic bond is detected in FIG. 8B and FIGS. 9-10, showing that no Cu⁰ species are formed.

TABLE 1
The fitting parameters of Cu K-edge EXAFS curves showing the
structure parameters around Cu in the Cu-M/1T′-WS₂ and Cu-M

| Sample | Shell | CN | R (Å) | σ² (Å²) | ΔE₀ (eV) | R-factor |
|---|---|---|---|---|---|---|
| Cu-M/1T′-WS₂ | Cu—O | 4.7 | 1.93 | 0.00742 | 2.586 | 0.0065633 |
| | Cu—C | 3.8 | 2.68 | 0.01257 | 8.621 | |
| Cu-M | Cu—O | 4.1 | 1.94 | 0.00474 | 0.006 | 0.0057803 |
| | Cu—C | 4.0 | 2.69 | 0.01137 | 3.959 | |

CN is the coordination number; R is the interatomic distance; σ² is the Debye-Waller factor; ΔE₀ is the inner potential correction; R-factor indicates the goodness of the fitting. The amplitude reduction factor (S₀²) was determined to be 0.98 from Cu foil fitting and fixed for all sample fitting.

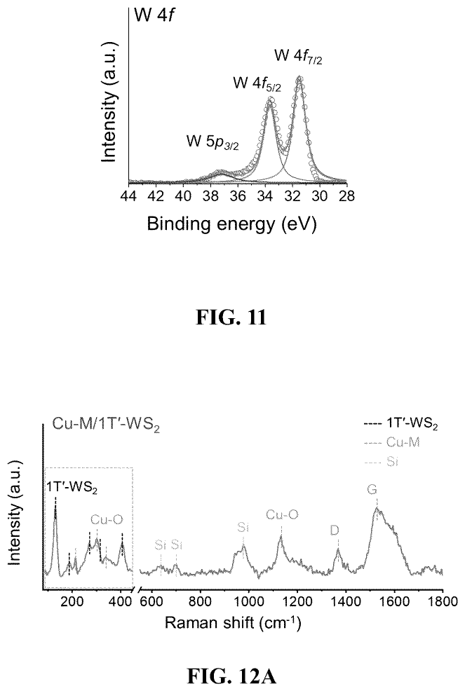

X-ray photoelectron spectroscopy (XPS) was used to further investigate the valence state of Cu in Cu-M/1T′-WS₂. As shown in FIG. 8D, the deconvoluted Cu 2p_{3/2} peaks at 932.6 eV and 934.0 eV can be assigned to Cu⁺ and Cu²⁺, respectively. The XPS spectra reveal that Cu in Cu-M/1T′-WS₂ exhibits a higher Cu⁺/Cu²⁺ ratio compared with Cu-M, consistent with the XANES results. The W 4f XPS spectra of Cu-M/1T′-WS₂ (FIG. 11), which match those of the 1T′-WS₂ nanosheets, confirm that there is no phase transition of 1T′-WS₂ after Cu-M growth.

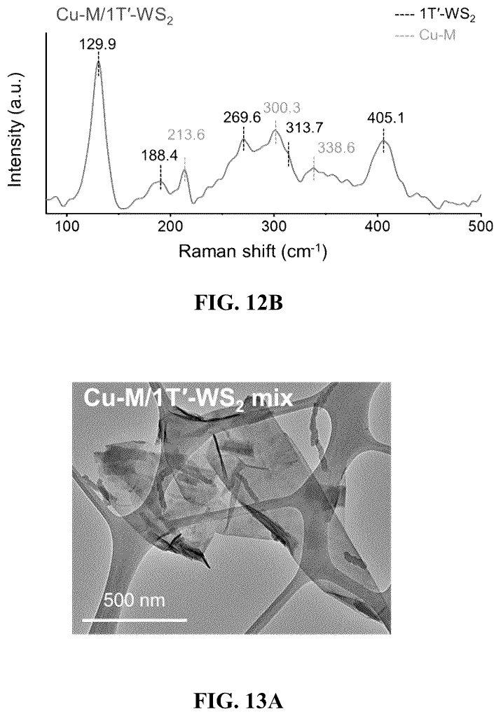

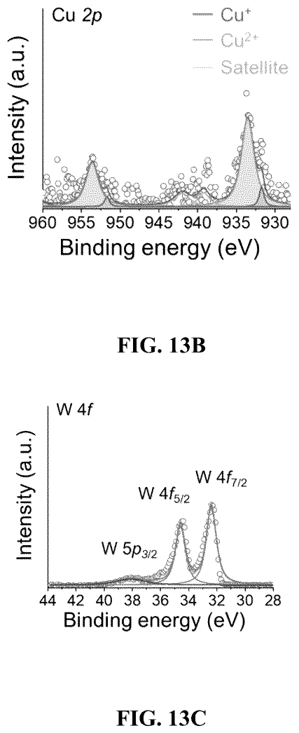

Raman and FTIR spectroscopy were employed to probe the vibrational and chemical environments in Cu-M/1T′-WS₂. As shown in FIG. 8E, the Raman spectrum of Cu-M/1T′-WS₂ exhibits characteristic peaks from both Cu-M and 1T′-WS₂. Five characteristic peaks of 1T′-WS₂ are observed, indicating that the 1T′ phase is preserved after Cu-M growth (FIG. 8E and FIG. 11). The G band at 1528.4 cm⁻¹ is attributed to the stretching of aromatic C—C bonds, and the D band at 1368.5 cm⁻¹ is ascribed to the breathing mode of the aromatic carbon ring (FIG. 8E and FIGS. 12A-12B), in good agreement with the spectra of Cu-M (FIGS. 13A-13C) and literature values⁷⁻⁹. Additional peaks at 213.6, 300.3, 338.6, and 1133.4 cm⁻¹ correspond to Cu—O vibrations in Cu-M. The coexistence of the characteristic 1T′-WS₂ peaks, the G and D bands, and the Cu—O-related peaks in the Cu-M/1T′-WS₂ spectrum confirms the formation of the heterostructure. The FTIR spectrum in FIG. 8F shows that the intensity of the C—OH band near 10⁰⁰ cm⁻¹ and the O—H stretching band at approximately 3000-3500 cm⁻¹ is significantly decreased relative to the HHTP ligand, indicating deprotonation and formation of Cu—O bonds. In addition, the appearance of a C═O vibration band at 1639 cm⁻¹ in Cu-M/1T′-WS₂ suggests electron redistribution at the oxygen atoms associated with partial ligand oxidation during framework formation.

### Example 6—Electromagnetic-Wave Absorption Performance and Mechanism Analysis

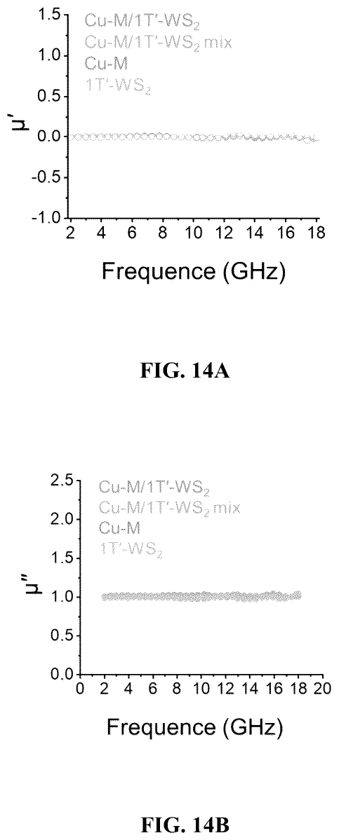

The EMW absorption performance of the Cu-M/1T′-WS₂ heterostructure was evaluated by measuring its complex permittivity (εᵣ=ε′−jε″) in the 2-18 GHz frequency range. As confirmed in FIGS. 14A-14B, all samples exhibit negligible magnetic responses, indicating that dielectric loss dominates their EMW attenuation behavior. For comparison, a physically mixed Cu-M/1T′-WS₂ sample (Cu-M/1T′-WS₂-mix) was prepared by directly mixing Cu-M with 1T′-WS₂ nanosheets, and pristine Cu-M and pristine 1T′-WS₂ nanosheets were also tested as reference materials.

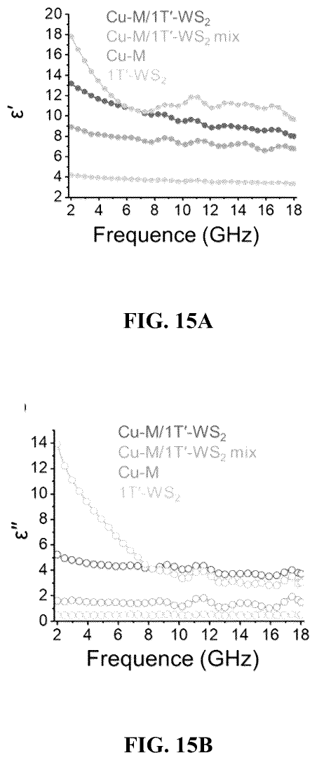

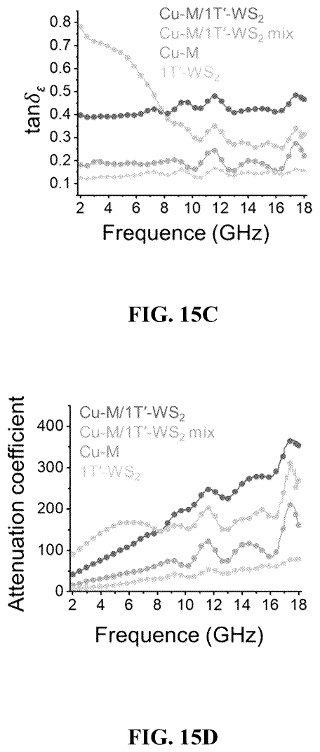

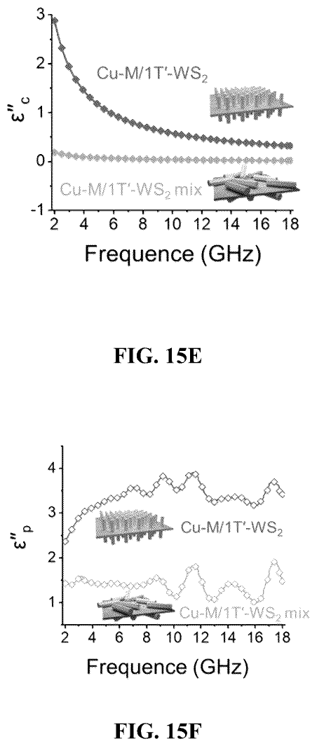

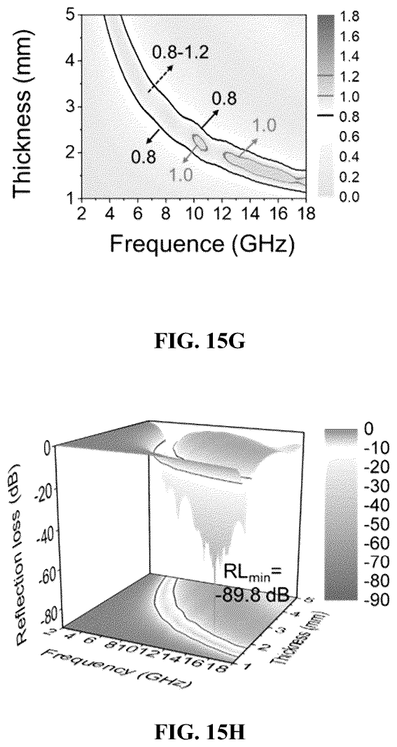

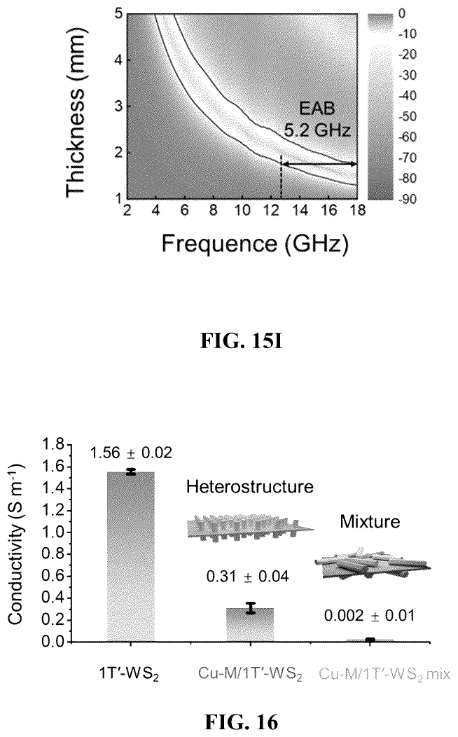

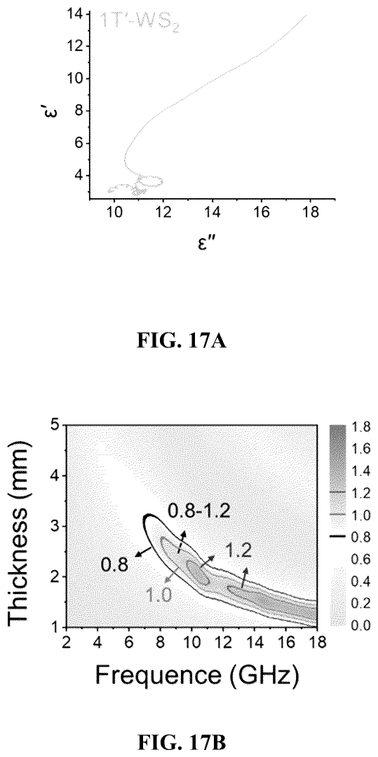

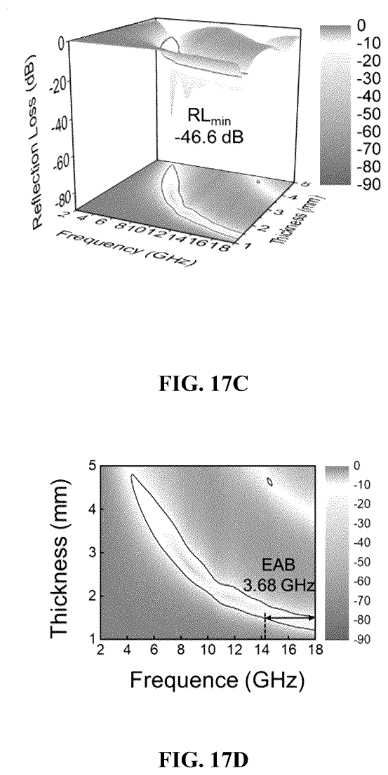

As shown in FIGS. 15A-15B, the Cu-M/1T′-WS₂ heterostructure exhibits ε′ values ranging from 13.19 to 8.00 and ε″ values from 5.24 to 3.52. In contrast, the Cu-M/1T′-WS₂-mix displays substantially lower ε′ (8.91-6.79) and ε″ (1.61-1.50) values despite its identical chemical composition. The pristine 1T′-WS₂ nanosheets show high ε′ (17.82-9.69) and ε″ (13.96-3.05) values due to their high electrical conductivity (FIG. 16), resulting in strong conduction loss and relatively strong attenuation capability (FIG. 17A). However, the excessively high permittivity of 1T′-WS₂ leads to poor impedance matching (FIG. 17B), where the impedance-matching region (Z=0.8-1.2) is narrow. Consequently, 1T′-WS₂ exhibits only moderate EMW absorption performance (FIGS. 17C-17D).

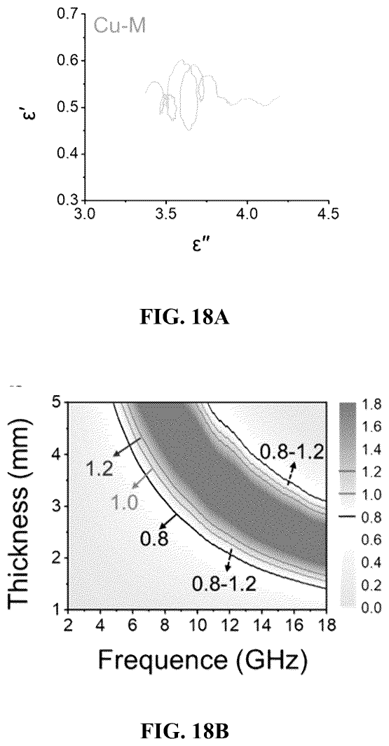

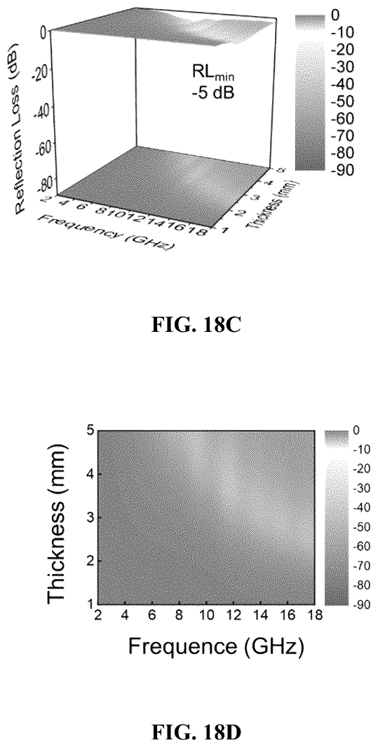

The Cu-M sample exhibits the lowest ε′ and ε″ values because of its limited electrical conductivity, resulting in weak attenuation (FIGS. 15C-15D) and poor EMW absorption (FIGS. 18A-18D). Combining Cu-M with conductive 1T′-WS₂ therefore provides an opportunity to tune the dielectric response. As evidenced in FIGS. 15A-15D, the Cu-M/1T′-WS₂ heterostructure simultaneously increases ε′, ε″, dielectric tangent loss, and attenuation coefficients compared with the Cu-M/1T′-WS₂-mix sample. These improvements arise from the presence of a coherent epitaxial interface, which enhances interfacial polarization and facilitates more effective dissipation of electromagnetic energy. The data confirm that van der Waals epitaxy, rather than simple physical mixing, is responsible for the superior dielectric behavior of the heterostructure.

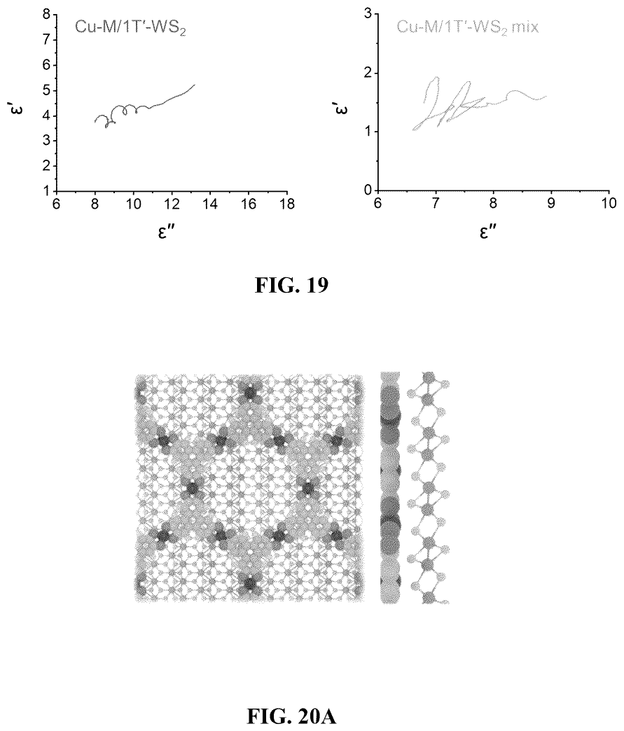

To distinguish the contributions of polarization loss and conduction loss, ε″ was partitioned into ε″ₚ (polarization loss) and ε″_{c} (conduction loss) components following established theoretical models¹⁰. As shown in FIGS. 15E-15F, ε″_{c} values of Cu-M/1T′-WS₂ (2.88-0.32) are substantially higher than those of the mixed sample (0.19-0.02), consistent with the higher conductivity of the epitaxial heterostructure (FIG. 19). In addition, ε″ₚ values of Cu-M/1T′-WS₂ (3.41-2.36) exceed those of the mixed sample (1.48-1.42), which can be attributed to the abundant heterogeneous epitaxial interfaces that promote interfacial polarization.

The Cole-Cole plots (FIG. 19) further illustrate differences in dielectric relaxation behavior. Based on Debye relaxation theory, each semicircle corresponds to a polarization relaxation process, while the slope of the linear region reflects conduction loss. The Cu-M/1T′-WS₂ heterostructure exhibits more semicircles and a steeper linear segment than the mixed material, confirming enhanced polarization relaxation and conduction loss.

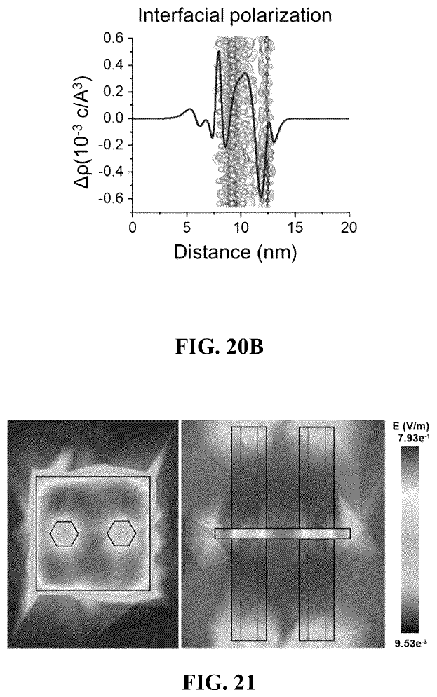

To further elucidate the polarization mechanism, the charge density difference of the Cu-M/1T′-WS₂ heterostructure was calculated based on the DFT model in FIG. 4G and FIGS. 20A-20B. The results show significant charge redistribution at the epitaxial interface, characterized by charge depletion on the Cu-M side and charge accumulation on the 1T′-WS₂ side. This asymmetric charge distribution indicates strong interfacial polarization, which is known to enhance EMW absorption.

Electromagnetic field simulations using a high-frequency structure simulator (HFSS) were conducted to evaluate polarization behavior under alternating electric fields. As shown in FIG. 21, the Cu-M/1T′-WS₂ interface shows significant charge accumulation, forming micro-capacitive structures between the dielectric Cu-M and conductive 1T′-WS₂. These micro-capacitors facilitate repeated charge migration under alternating electric fields, resulting in strong polarization loss. This polarization-dominant mechanism also mitigates impedance mismatch caused by excessive conduction loss.

The impedance matching behavior of Cu-M/1T′-WS₂ is shown in FIG. 15G, in which the light-red region (Z=0.8-1.2) indicates efficient impedance matching¹¹. The broad impedance-matching area shows that EMWs can effectively enter the absorber rather than being reflected at the surface.

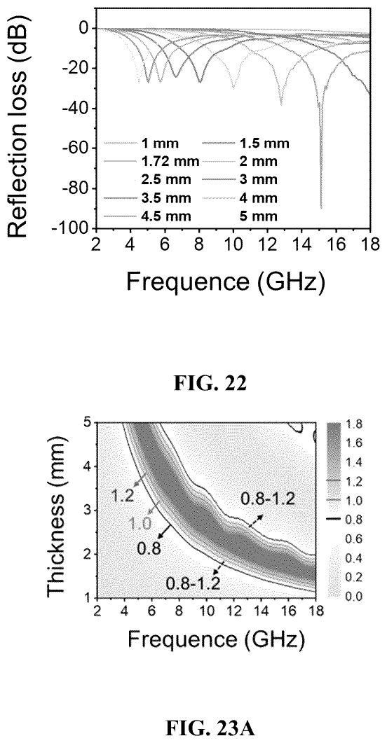

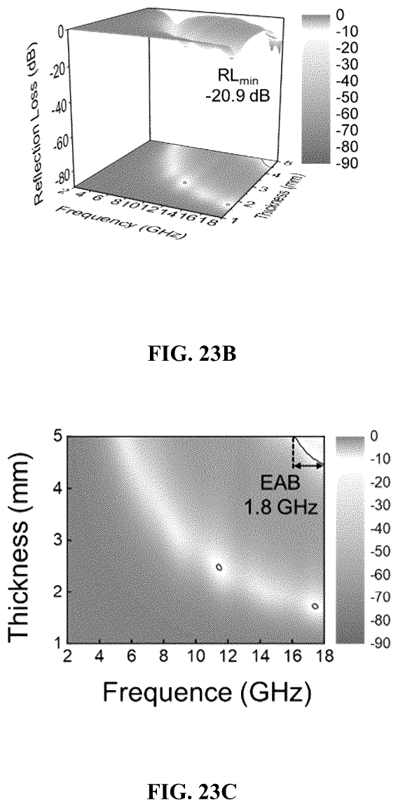

Benefiting from the synergistic contributions of conduction loss, polarization loss, and optimized impedance matching, the Cu-M/1T′-WS₂ heterostructure achieves an ultralow minimum reflection loss (RLₘᵢₙ) of −89.8 dB (FIG. 15H and FIG. 22), which, to the best of our knowledge, represents the strongest absorption among all reported non-magnetic EMW absorbents. Furthermore, Cu-M/1T′-WS₂ exhibits a broad effective absorption bandwidth (EAB) of 5.2 GHz (FIG. 15I), enabled by stable impedance matching across a wide frequency range. In comparison, the physical mixture Cu-M/1T′-WS₂-mix shows significantly inferior EMW absorption performance (FIGS. 23A-23C).

### Example 7—Additional Structural Modeling and Spectroscopic Analysis Applicable to Other MOF/TMD Interfaces

In addition to the specific Cu based MOF and 1T′-WS₂ heterostructures described in the preceding examples, the present invention further encompasses other combinations of metal organic frameworks and transition metal dichalcogenide nanosheets. The following analysis provides an additional embodiment that illustrates a general approach for evaluating lattice alignment and interfacial stability in MOF/TMD systems beyond the Cu-M/1T′-WS₂ heterostructure described previously.

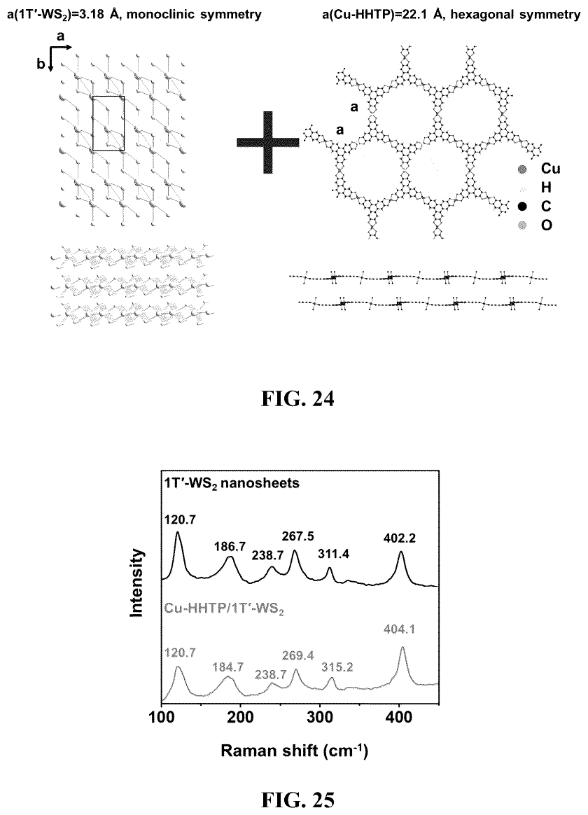

As illustrated in FIG. 24, a lattice schematic can be used to examine the geometric relationship between a planar conjugated MOF ligand and the basal plane of a 1T′-phase TMD nanosheet. Although FIG. 24 depicts the orientation of a conjugated ligand on a 1T′-WS₂ lattice, the interfacial arrangement shown in this schematic is representative of the van der Waals epitaxial interactions that may occur across a wide variety of MOF and TMD materials. The ordered atomic arrangement of the TMD basal plane provides a crystallographic framework that can guide the orientation of an overlying MOF layer in the absence of covalent bonding or lattice matching requirements. This schematic therefore illustrates a general principle that can be used to understand epitaxial alignment in other MOF/TMD combinations within the scope of the present invention.

Raman spectroscopy can also be used to analyze additional MOF/TMD composites in order to verify the coexistence of both MOF and TMD vibrational signatures at the interface. As shown in FIG. 25, a MOF/TMD composite displays the characteristic vibrational modes of the TMD along with the G and D bands associated with a conjugated MOF ligand. The simultaneous appearance of these spectral features confirms that the MOF is assembled on the TMD surface while preserving the intrinsic vibrational characteristics of both components. The absence of peak shifts associated with TMD phase changes further indicates that the assembly process does not perturb the structural integrity of the TMD lattice. These observations are applicable to a broad range of MOF/TMD systems and are not limited to any specific combination.

This example therefore supports the general applicability of the disclosed methods and confirms that the invention is not restricted to the specific Cu based MOF and 1T′-WS₂ heterostructures described in Examples 1 through 6.

### Example 8—Epitaxial Growth of 1D Cu-HHTP Nanorods on 1T′-WS₂ Nanosheets

In addition to the 2D Cu based metal organic framework structures described in the preceding examples, the present invention also encompasses the formation of 1D MOF morphologies on metastable transition metal dichalcogenide nanosheets. This example provides an embodiment in which Cu-HHTP nanorods are formed on 1T′-WS₂ nanosheets through a solution based epitaxial growth process. The purpose of this example is to demonstrate that the van der Waals epitaxial strategy disclosed in the present invention is applicable to MOFs with different dimensionalities and does not require the MOF to possess a 2D layered structure.

In this embodiment, 1T′-WS₂ nanosheets were dispersed in a mixed solvent containing water and a polar organic solvent under mild stirring. A precursor solution containing the HHTP ligand and copper salt was added dropwise under controlled concentration and temperature conditions to initiate directional coordination. Under these growth conditions, anisotropic nucleation occurs preferentially along the conjugated HHTP backbone, resulting in the formation of elongated Cu-HHTP nanorods. The presence of the 1T′-WS₂ template facilitates ordered growth along the nanorod axis through noncovalent interactions. FIG. 3 shows transmission electron microscopy images of the resulting heterostructure, in which Cu-HHTP nanorods can be observed anchored on the surface of the 1T′-WS₂ nanosheets.

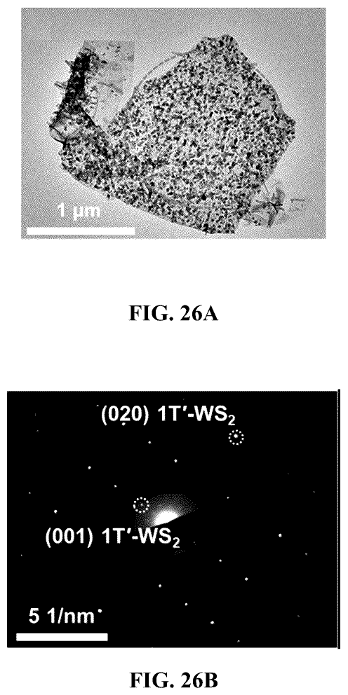

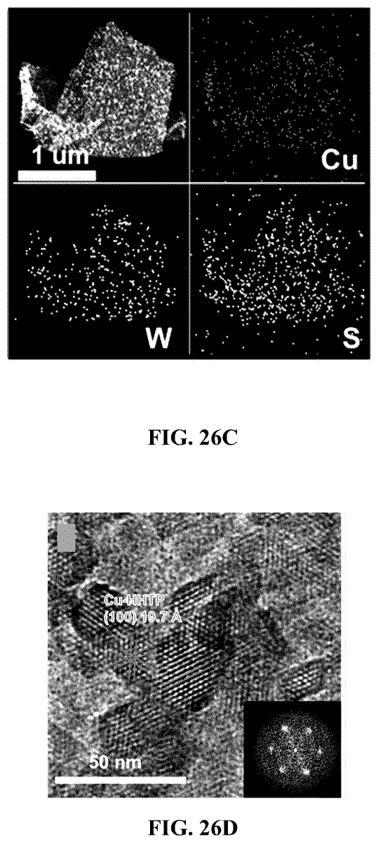

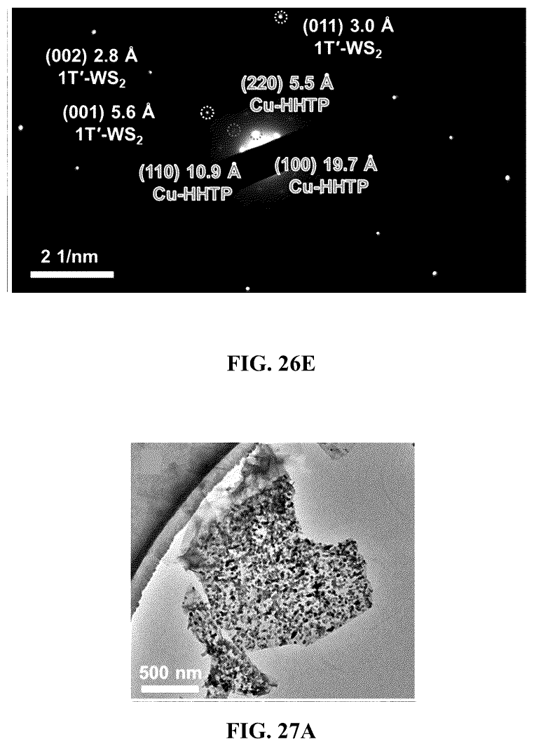

The nanorods exhibit a uniform diameter and a well-defined longitudinal orientation relative to the underlying TMD nanosheet. Referring to FIGS. 26A-26E, the SAED confirm the crystalline nature of the nanorod structures. Elemental mapping reveals that copper and oxygen signals are predominantly localized within the nanorod domains while tungsten and sulfur signals originate from the nanosheet substrate. These results confirm that Cu-HHTP nanorods are assembled directly onto the surface of the 1T′-WS₂ template without forming covalent bonds or altering the basal plane of the TMD. The successful formation of Cu-HHTP nanorods on 1T′-WS₂ nanosheets demonstrates that the epitaxial van der Waals assembly method of the present invention can accommodate MOF architectures with different structural dimensionalities. The formation of 1D MOF morphologies is enabled by the intrinsic anisotropy of the conjugated ligand and the ordered atomic arrangement of the TMD basal plane. This example further confirms that the disclosed strategy is general and does not require the MOF to share a 2D crystal lattice with the TMD substrate. Accordingly, this embodiment supports the applicability of the present invention to a broad range of MOF structures, including 1D, 2D, and three dimensional (3D) frameworks.

### Example 9—Epitaxial Growth of Cu-HHTP MOF on 1T′-MoS₂ Nanosheets

In order to demonstrate that the van der Waals epitaxial strategy disclosed in the present invention is applicable to other transition metal dichalcogenide templates, this example describes an embodiment in which the Cu-M metal organic framework is grown on metastable 1T′-MoS₂ nanosheets. This example provides additional support for the general applicability of the disclosed method and confirms that the invention is not limited to WS₂ based substrates.

High purity 1T′-MoS₂ nanosheets were first obtained through an electrochemical intercalation and exfoliation procedure similar to that described in Examples 1 and 2, with the MoS₂ precursor substituted for WS₂. The resulting 1T′-MoS₂ nanosheets exhibited sheet like morphology and uniform thickness. These nanosheets were dispersed in a mixed aqueous and organic solvent to form a stable colloidal suspension. A precursor solution containing the HHTP ligand and copper salt was then introduced under controlled concentration, pH, and temperature conditions to allow nucleation and growth of the Cu-M framework.

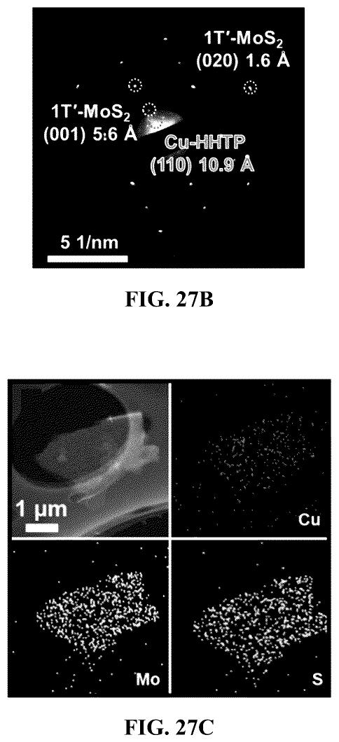

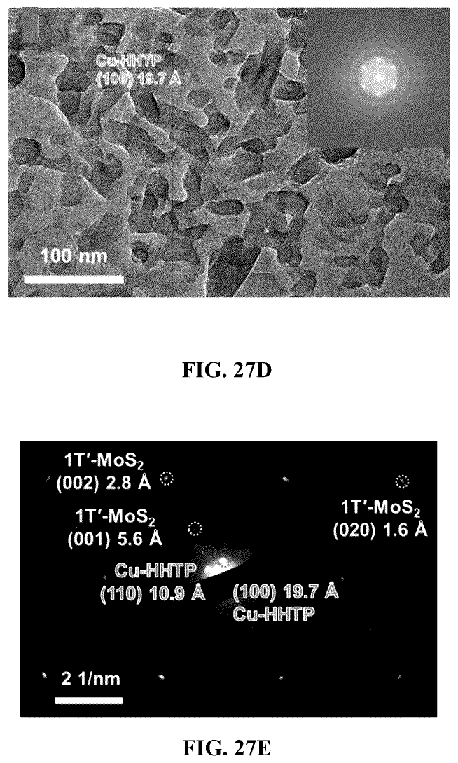

Under the selected reaction conditions, Cu-M nanostructures formed preferentially on the basal planes of the 1T′-MoS₂ nanosheets. FIG. 27A shows TEM images of the resulting heterostructure. Distinct Cu-M domains can be observed distributed across the MoS₂ surface. These domains exhibit well defined crystalline order and maintain a consistent orientation relative to the underlying TMD nanosheet. FIGS. 27B-27E further shows corresponding SAED, which demonstrate the presence of both the Cu-M lattice and the 1T′-MoS₂ lattice in the composite structure. The observed diffraction spots confirm the coexistence of the two phases and indicate that the Cu-M framework adopts a preferred crystallographic orientation on the MoS₂ substrate through van der Waals guided epitaxy.

Elemental mapping analysis confirms the spatial distribution of copper and oxygen within the MOF domains and verifies that molybdenum and sulfur signals originate from the nanosheet substrate. No evidence of chemical bonding between copper species and sulfur atoms is observed. These results indicate that the Cu-M framework is anchored through noncovalent interactions rather than through the formation of covalent Cu—S bonds. The basal plane of the 1T′-MoS₂ nanosheet remains structurally intact, which demonstrates that the growth of the Cu-M layer does not induce detrimental phase changes in the TMD template.

The successful formation of Cu-M on 1T′-MoS₂ nanosheets confirms that the van der Waals epitaxial strategy disclosed in the present invention is not limited to WS₂ based systems. This example demonstrates that metastable MoS₂ can also serve as an effective template for the oriented growth of metal organic frameworks. Accordingly, this embodiment supports the breadth of the present invention and enables claims covering multiple TMD compositions, including MoS₂, WS₂, MoSe₂, WSe₂, TiS₂, and related materials.

### Example 10—Epitaxial Growth of 2D Cu-TCPP MOF on 1T′-WS₂ Nanosheets

In order to further illustrate the general applicability of the disclosed method to different classes of metal organic frameworks, this example describes an embodiment in which a 2D porphyrinic framework, Cu-TCPP, is grown on 1T′-WS₂ nanosheets. This embodiment demonstrates that the invention supports MOFs having different coordination geometries, ligand sizes, and in plane structural dimensions.

A suspension of high quality 1T′-WS₂ nanosheets was first prepared according to the methods described in Examples 1 and 2. The nanosheets were dispersed to form a stable colloidal solution in a mixed aqueous and organic medium. A ligand solution containing tetrakis(4-carboxyphenyl) porphyrin (TCPP) was prepared separately and mixed with a copper precursor under controlled reaction conditions. The mixed precursor solution was then introduced into the nanosheet suspension and allowed to react under a controlled temperature profile.

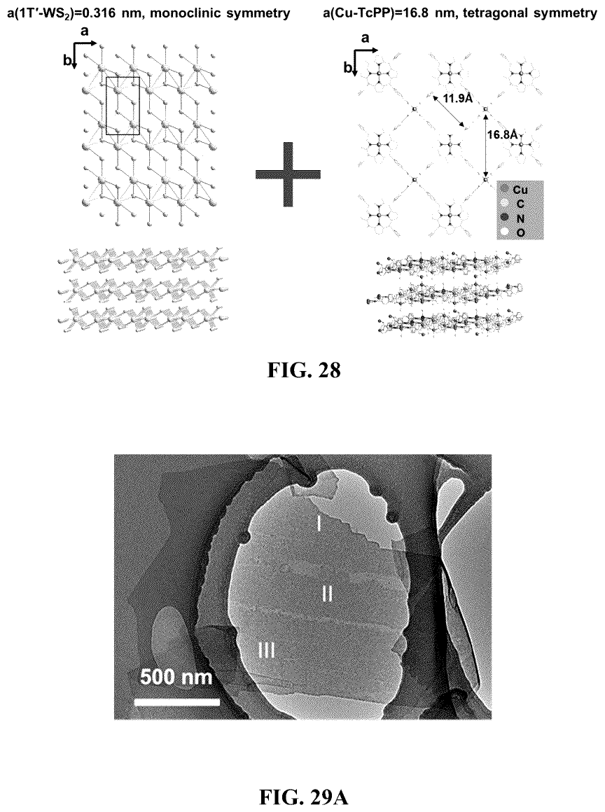

Under these reaction conditions, 2D Cu-TCPP domains formed and anchored onto the basal surface of the 1T′-WS₂ nanosheets. FIG. 28 shows a structural model depicting the relative orientation between the Cu-TCPP lattice and the 1T′-WS₂ lattice. The porphyrinic macrocycle presents a planar framework with extended π conjugation. This planar structure facilitates strong interactions with the basal plane of the 1T′-WS₂ nanosheet and allows the Cu-TCPP framework to adopt a preferred orientation at the interface. The schematic in FIG. 28 illustrates the spatial registry between the Cu-TCPP unit cell and the surface lattice of the TMD substrate.

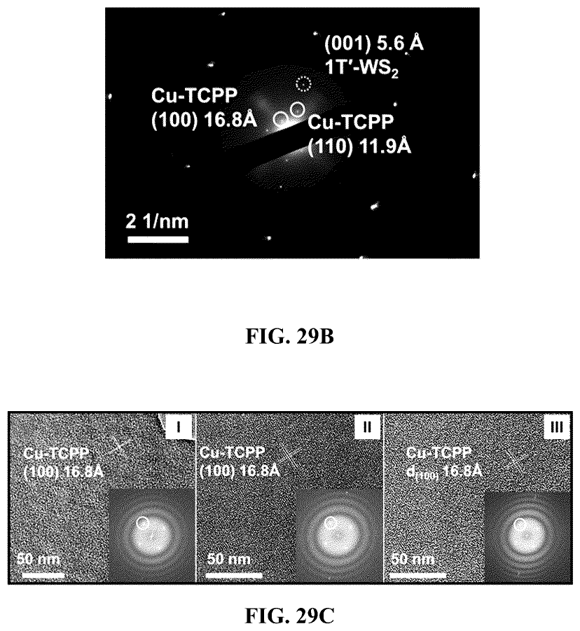

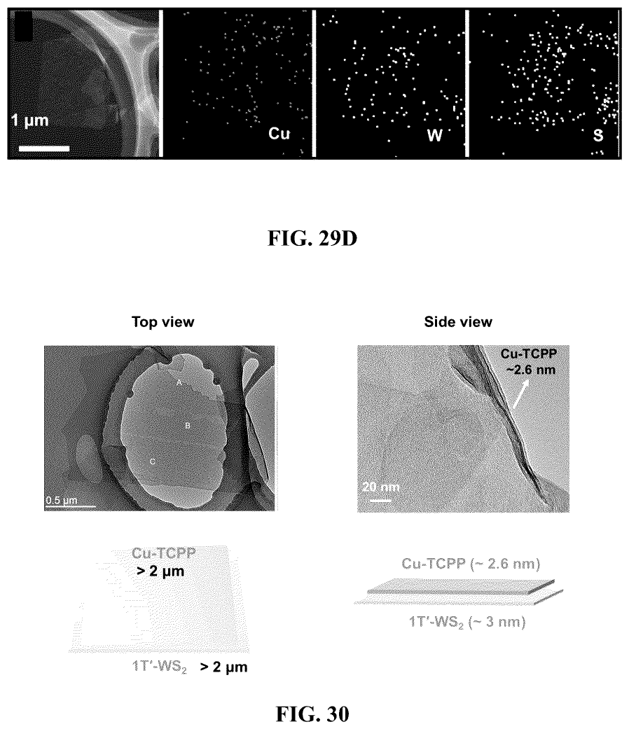

The formation of the heterostructure was confirmed using transmission electron microscopy. FIG. 29A shows a representative high resolution TEM image of the Cu-TCPP and 1T′-WS₂ composite. Distinct Cu-TCPP domains can be observed with a uniform crystallographic orientation. Referring to FIGS. 29B-29D, the corresponding SAED exhibits diffraction features associated with both the Cu-TCPP lattice and the 1T′-WS₂ lattice. The relative alignment of these two diffraction patterns confirms that the Cu-TCPP framework grows in an ordered manner on the TMD nanosheet through van der Waals guided epitaxy. This indicates that the epitaxial relationship is not limited to the Cu-HHTP framework described in the earlier examples.

Large area imaging further demonstrates the scalability of the epitaxial process. FIG. 30 shows an extended field TEM survey of the Cu-TCPP and 1T′-WS₂ heterostructure. Uniformly distributed Cu-TCPP sheets can be observed across the nanosheet substrate. The domains exhibit consistent lateral dimensions and maintain a uniform crystallographic orientation throughout the imaged region. This large area uniformity indicates that the wet chemical epitaxial growth method can be extended to porphyrinic MOFs and can be applied across macroscopic substrate areas.

Combined TEM, SAED, and elemental mapping analysis confirm that the Cu-TCPP domains are distributed exclusively on the basal surface of the 1T′-WS₂ nanosheets. No evidence of covalent bonding between copper species and sulfur atoms is observed. The interface is preserved as a van der Waals junction and does not induce structural degradation of the underlying TMD lattice. These results demonstrate that porphyrinic frameworks with large planar ligands can also participate in van der Waals epitaxy on TMD nanosheets. The successful formation of the Cu-TCPP and 1T′-WS₂ epitaxial heterostructure confirms that the method disclosed in the present invention is applicable to multiple classes of metal organic frameworks, including 2D porphyrin based structures.

### Example 11—MOFs with Tunable Metal Centers and Mixed-Metal Epitaxial Growth

The preceding examples establish that the van der Waals epitaxial method of the present invention enables the controlled growth of metal organic frameworks having different ligand structures on metastable TMD nanosheets. In order to further demonstrate the generality of the invention and to support MOFs having tunable and mixed-metal centers, the present example provides embodiments in which the metal nodes of the porphyrinic framework are varied between single-metal and dual-metal compositions.

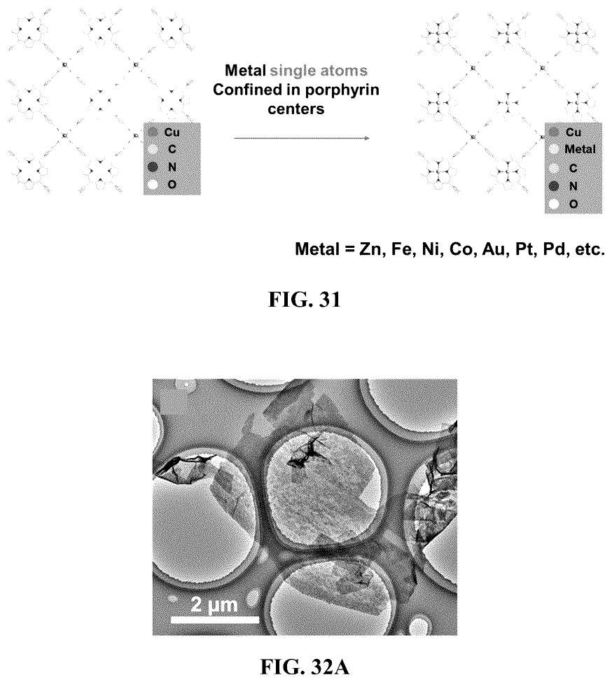

2D porphyrin-based ligands were selected as the coordination units for this set of experiments. FIG. 31 illustrates the structural characteristics of the porphyrinic MOF platform used in this example. The ligand framework is capable of coordinating different metal ions, and the atomically defined metal sites are located at the center of the porphyrin macrocycle. This structural feature allows the metal center to be replaced or supplemented with alternative metal ions without altering the planar geometry of the ligand.

Single-metal Cu-TCPP and Ni-TCPP frameworks were prepared by coordinating the TCPP ligand with copper or nickel precursors under the same solution-phase reaction conditions described in Example 10. The resulting products were subsequently introduced into suspensions of 1T′-WS₂ nanosheets. The growth process produced epitaxial MOF domains that maintained a uniform orientation relative to the underlying TMD lattice. The structural modeling in FIG. 31 confirms that the coordination geometry of the single-metal center remains compatible with van der Waals epitaxy.

To demonstrate mixed-metal incorporation, a precursor mixture containing copper and nickel salts was prepared at a controlled stoichiometric ratio. The mixed-metal precursor solution was added to the TCPP ligand under the same reaction environment described previously. The resulting Cu—Ni-TCPP complex was then brought into contact with the 1T′-WS₂ nanosheet suspension to initiate van der Waals guided epitaxial growth.

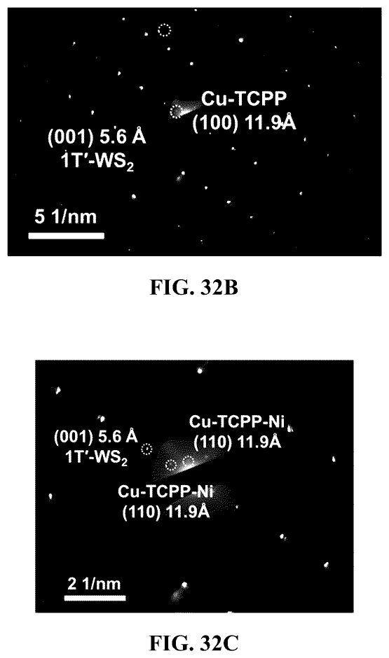

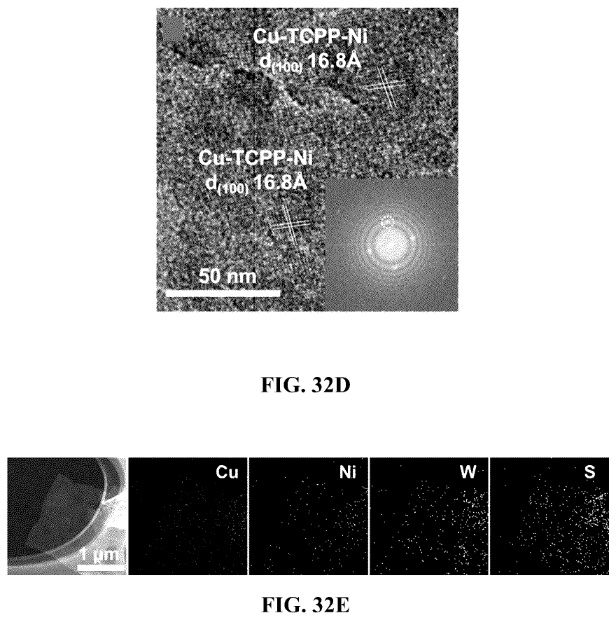

FIGS. 32A-32E present a representative structural model and microscopic characterization of the Cu—Ni-TCPP and 1T′-WS₂ heterostructures. The image shows that uniformly oriented 2D MOF domains are anchored on the TMD nanosheets. Energy-dispersive X-ray spectroscopy mapping confirms the presence of both Cu and Ni species within the same MOF domain. The colocalization of the two metals indicates that the Cu and Ni ions are incorporated within the porphyrin centers rather than segregating into independent phases. This embodiment confirms that the present invention supports frameworks comprising two or more metal species within the same coordination environment. Selected area electron diffraction and high resolution imaging show that the epitaxial relationship between the MOF and the 1T′-WS₂ nanosheet is preserved in both the single-metal and mixed-metal embodiments. The diffraction spots corresponding to the MOF domains overlap with those of the underlying TMD in a consistent orientation throughout the imaged area. These results demonstrate that modification of the metal center does not disrupt the van der Waals epitaxial alignment.

The results of this example confirm that the metal centers of the MOF component may be selected from a broad range of transition metals without loss of epitaxial compatibility. Single-metal embodiments include copper, nickel, cobalt, iron, manganese, zinc, and related transition metal ions. Mixed-metal embodiments include combinations of these metal ions incorporated within a single porphyrin based framework.

In summary, the present invention provides a general and scalable strategy for constructing organic inorganic van der Waals epitaxial heterostructures in which a metal organic framework is epitaxially grown on a metastable 1T′ phase transition metal dichalcogenide nanosheet. The method is compatible with various MOF structures and metal centers, including mixed metal systems, and is applicable to multiple TMD templates such as 1T′-WS₂ and 1T′-MoS₂, while also accommodating different MOF morphologies.

The resulting epitaxial interface exhibits a well defined crystallographic relationship and enables electronic and dielectric interactions that cannot be achieved through physical mixing. Experimental characterization and theoretical modeling confirm that the van der Waals interface induces strong interfacial polarization and favorable charge redistribution.

These features allow the heterostructures to exhibit superior functional properties. For example, the Cu-M/1T′-WS₂ heterostructure achieves a minimum reflection loss of −89.8 dB and a broad effective absorption bandwidth. The additional embodiments involving alternative MOFs, alternative TMDs, and mixed metal centers further demonstrate the versatility and broad applicability of the disclosed strategy.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments are chosen and described in order to best explain the principles of the invention and its practical application, thereby enabling others skilled in the art to understand the invention for various embodiments and with various modifications that are suited to the particular use contemplated.

### Definitions

Throughout this specification, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. Patent law; e.g., they allow for elements not explicitly recited, but exclude elements that are found in the prior art or that affect a basic or novel characteristic of the present invention.

Furthermore, throughout the specification and claims, unless the context requires otherwise, the word “include” or variations such as “includes” or “including”, will be understood to imply the inclusion of a stated integer or group of integers but not the exclusion of any other integer or group of integers.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to #0.1%, or less than or equal to ±0.05%.

References in the specification to “one embodiment”, “an embodiment”, “an example embodiment”, etc., indicate that the embodiment described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

In the methods of preparation described herein, the steps can be carried out in any order without departing from the principles of the invention, except when a temporal or operational sequence is explicitly recited. Recitation in a claim to the effect that first a step is performed, and then several other steps are subsequently performed, shall be taken to mean that the first step is performed before any of the other steps, but the other steps can be performed in any suitable sequence, unless a sequence is further recited within the other steps. For example, claim elements that recite “Step A, Step B, Step C, Step D, and Step E” shall be construed to mean step A is carried out first, step E is carried out last, and steps B, C, and D can be carried out in any sequence between steps A and E, and that the sequence still falls within the literal scope of the claimed process. A given step or sub-set of steps can also be repeated. Furthermore, specified steps can be carried out concurrently unless explicit claim language recites that they be carried out separately.

As used herein, the term “van der Waals epitaxial heterostructure” refers to a layered composite structure in which an overlying material grows on a crystalline substrate with a defined crystallographic orientation guided by interlayer van der Waals interactions rather than covalent, ionic, or metallic bonding. The epitaxial alignment is established without requiring lattice matching within conventional epitaxial tolerance limits and without formation of interfacial chemical bonds.

The term “metastable 1T′ phase” refers to a distorted octahedral coordination structure of a transition-metal dichalcogenide characterized by zigzag metal-metal chains and identifiable by Raman modes, X-ray photoelectron spectroscopy, or electron diffraction. The 1T′ phase is distinct from the semiconducting 2H phase and the symmetric metallic 1T phase, and exists as a kinetically stabilized polymorph under ambient conditions.

The terms “basal surface” and “basal plane” refer to the major surface of a layered transition-metal dichalcogenide corresponding to its {001}-type crystallographic planes, which extend parallel to the two-dimensional van der Waals layers.

The term “epitaxial crystallographic orientation” refers to a fixed angular relationship between lattice planes of an overlying material and lattice planes of a substrate, detectable by selected-area electron diffraction, fast Fourier transform analysis of transmission electron microscopy images, or equivalent crystallographic characterization.

The term “planar π-conjugated ligand plane” refers to a ligand structure in which aromatic or heteroaromatic rings form an extended π-electron system arranged in a substantially coplanar configuration. The plane of the ligand corresponds to the geometric plane defined by the aromatic core.

The term “metal-organic framework” refers to a coordination network comprising metal ions or metal clusters connected by organic ligands to form a periodic structure having a defined lattice. The term includes two-dimensional, one-dimensional, and mixed-dimensional frameworks.

The term “mixed-metal center” refers to a metal-organic framework in which two or more different metal ions occupy coordination sites within the same ligand framework or within the same multinuclear metal node, rather than forming separate phase-segregated particles.

The term “orientation deviation” refers to an angular difference between crystallographic axes of multiple metal-organic framework domains relative to a reference axis of the underlying nanosheet, as measured by selected-area electron diffraction or fast Fourier transform analysis.

The term “periodic in-plane lattice spacing” refers to a repeated distance between equivalent atomic positions within the plane of a metal-organic framework or a transition-metal dichalcogenide lattice, determined by electron diffraction or high-resolution transmission electron microscopy.

The term “lattice registry” refers to a condition in which periodic features of two crystalline lattices maintain a defined spatial correspondence or alignment across an interface.

The term “colloidal suspension” refers to a stable dispersion of nanosheets in a liquid medium in which the nanosheets remain distributed without sedimentation for a period sufficient to carry out the coordination reaction.

As used herein, the term “π-plane adsorption” refers to a non-covalent interaction in which a planar π-conjugated ligand aligns its aromatic electron cloud parallel to the basal plane of a transition-metal dichalcogenide nanosheet. The interaction is mediated by π-π stacking, quadrupole interactions, and dispersive van der Waals forces, thereby promoting a preferred in-plane orientation of the ligand relative to the nanosheet surface. π-plane adsorption, as defined herein, excludes covalent metal-chalcogen bond formation and does not require lattice matching between the adsorbed ligand and the underlying nanosheet.

The term “van der Waals interface” refers to a junction between two layered or molecular materials in which interlayer binding is governed solely by dispersive van der Waals forces, π-π interactions, or other non-covalent interactions without formation of chemical bonds across the interface. A van der Waals interface, as used herein, maintains a measurable interlayer spacing larger than that of a covalently bonded interface and preserves the intrinsic electronic structure of each component. In the present disclosure, the van der Waals interface enables crystallographic epitaxy between a metal-organic framework and a 1T′-phase transition-metal dichalcogenide despite substantial lattice mismatch.

As used herein, “epitaxy” refers to an ordered growth relationship in which a material is formed on a substrate with a defined crystallographic orientation correlated to that of the substrate. In the present invention, epitaxy includes van der Waals epitaxy, in which the overlayer and the substrate are coupled through non-covalent van der Waals interactions rather than lattice matching or covalent bonding, such that a consistent crystallographic alignment can be established even in the presence of differences in lattice constants or minor lattice spacing deviations.

Other definitions for selected terms used herein may be found within the detailed description of the present invention and apply throughout. Unless otherwise defined, all other technical terms used herein have the same meaning as commonly understood to one of ordinary skill in the art to which the present invention belongs.

### REFERENCES: THE DISCLOSURES OF THE FOLLOWING REFERENCES ARE INCORPORATED BY REFERENCE

1. US20230416935A1
2. Zeng, Z., Yin, Z., Huang, X., Li, H., He, Q., Lu, G., . . . & Zhang, H. (2011). Single-layer semiconducting nanosheets: high-yield preparation and device fabrication. Angewandte Chemie-International Edition, 50 (47), 11093-11097.
3. Lin, Z., Liu, Y., Halim, U., Ding, M., Liu, Y., Wang, Y., . . . & Duan, X. (2018). Solution-processable 2D semiconductors for high-performance large-area electronics. Nature, 562 (7726), 254-258.
4. Huang, X., Zeng, Z., Bao, S., Wang, M., Qi, X., Fan, Z., & Zhang, H. (2013). Solution-phase epitaxial growth of noble metal nanostructures on dispersible single-layer molybdenum disulfide nanosheets. Nature communications, 4 (1), 1444.
5. Shi, Z., Zhang, X., Lin, X., Liu, G., Ling, C., Xi, S., . . . & Zhang, H. (2023). Phase-dependent growth of Pt on MoS₂ for highly efficient H₂ evolution. Nature, 621 (7978), 300-305.
6. Lai, Z. et al. Metastable 1T′-phase group VIB transition metal dichalcogenide crystals. Nat. Mater. 20, 1113-1120 (2021).
7. Sun, J. et al. Self-sacrifice template construction of a conductive Cu (3) (HHTP) (2) nanowhisker arrays@copper foam toward robust lithium storage. Chem Commun (Camb) 60, 8423-8426 (2024).
8. Lim, H., Kwon, H., Kang, H., Jang, J. E. & Kwon, H. J. Semiconducting MOFs on ultraviolet laser-induced graphene with a hierarchical pore architecture for NO(2) monitoring. Nat Commun 14, 3114 (2023).
9. Ferralis, N. Probing mechanical properties of graphene with Raman spectroscopy. Journal of Materials Science 45, 5135-5149 (2010).
10. Qiao, J. et al. Non-Magnetic Bimetallic MOF-Derived Porous Carbon-Wrapped TiO(2)/ZrTiO(4) Composites for Efficient Electromagnetic Wave Absorption. Nanomicro Lett 13, 75 (2021).
11. Niu, Q., Huang, Y., Huang, H. & Zong, M. A Flexible and Repairable Ultra-Broadband Electromagnetic Wave Absorber by Liquid-Liquid Phase Separation Strategy. Adv Mater, e10139 (2025).

What is claim is:

1. A van der Waals epitaxial heterostructure, comprising: a transition-metal dichalcogenide nanosheet in a metastable 1T′ phase; and a metal-organic framework disposed on a basal surface of the transition-metal dichalcogenide nanosheet, wherein the metal-organic framework exhibits an epitaxial crystallographic orientation aligned with a lattice plane of the transition-metal dichalcogenide nanosheet through van der Waals interactions without formation of metal-chalcogen covalent bonds, and wherein a planar ligand plane of the metal-organic framework is oriented substantially parallel to the basal plane of the 1T′-phase nanosheet.

2. The van der Waals epitaxial heterostructure of claim 1, wherein the transition-metal dichalcogenide nanosheet comprises WS₂, MoS₂, MoSe₂, WSe₂, TiS₂, TiSe₂, TaS₂, TaSe₂, VS₂, VSe₂, NbS₂, NbSe₂, ReS₂, ReSe₂, or a mixed-chalcogenide analogue in a 1T′ phase.

3. The van der Waals epitaxial heterostructure of claim 1, wherein the metal-organic framework comprises a coordination network formed from a multinuclear metal node and a planar π-conjugated ligand.

4. The van der Waals epitaxial heterostructure of claim 3, wherein the ligand is selected from HHTP, TCPP, HHB, HAB, HTTP, HTTP, HHTN, HHTT, or functional derivatives thereof.

5. The van der Waals epitaxial heterostructure of claim 1, wherein a metal center of the metal-organic framework comprises Cu, Ni, Co, Fe, Mn, Zn, Rh, or a combination thereof.

6. The van der Waals epitaxial heterostructure of claim 5, wherein the metal-organic framework comprises a mixed-metal center in which at least two different metal ions occupy coordination sites within a single ligand framework.

7. The van der Waals epitaxial heterostructure of claim 1, wherein the metal-organic framework forms a two-dimensional nanosheet morphology.

8. The van der Waals epitaxial heterostructure of claim 1, wherein the metal-organic framework forms a one-dimensional nanorod morphology.

9. The van der Waals epitaxial heterostructure of claim 1, wherein the metal-organic framework is distributed across the basal plane of the nanosheet with an orientation deviation of less than 3 degrees across a lateral distance of at least 5 nm.

10. The van der Waals epitaxial heterostructure of claim 1, wherein the metal-organic framework exhibits a periodic in-plane lattice spacing that corresponds to a surface periodicity of the 1T′-phase nanosheet within a deviation of less than 10 percent, thereby defining a crystallographic registry at the interface.

11. A method of forming a van der Waals epitaxial heterostructure, comprising:
preparing a transition-metal dichalcogenide nanosheet in a metastable 1T′ phase;
dispersing the transition-metal dichalcogenide nanosheet in a liquid medium to form a colloidal suspension;
introducing a metal precursor and a planar π-conjugated ligand into the colloidal suspension; and
allowing the metal precursor and ligand to coordinate on a basal surface of the transition-metal dichalcogenide nanosheet to form a metal-organic framework that adopts an epitaxial crystallographic orientation aligned with a nanosheet lattice through van der Waals interactions.

12. The method of claim 11, wherein 1T′-phase nanosheet is prepared by electrochemical intercalation using a quaternary ammonium cation.

13. The method of claim 12, wherein the quaternary ammonium cation comprises tetraethylammonium, tetrapropylammonium, tetraheptylammonium, tetradecylammonium, or a combination thereof.

14. The method of claim 11, wherein the planar π-conjugated ligand is selected from HHTP, TCPP, HITP, HTTP, HHB, HAB, or derivatives thereof.

15. The method of claim 11, wherein the metal precursor comprises Cu²⁺, Ni²⁺, Co²⁺, Fe²⁺, Mn²⁺, Zn²⁺, Rh³⁺, or a combination thereof.

16. The method of claim 11, further comprising cooling the metal-organic framework to a temperature between 0° C. and 15° C. during an initial nucleation period to regulate ligand-metal coordination kinetics.

17. The method of claim 11, wherein the planar π-conjugated ligand in the reaction medium has a concentration in a range of 0.01 to 10 mg mL⁻¹.

18. The method of claim 11, wherein the metal precursor and the planar π-conjugated ligand have a molar ratio of 3:2.

19. The method of claim 11, wherein the coordination reaction is carried out for a duration of 0.5 to 72 hours to allow oriented metal-organic framework growth on the basal plane of the nanosheet.

20. The method of claim 11, wherein the liquid medium comprises water and an organic solvent selected from DMF, IPA, ethanol, acetonitrile, or mixtures thereof.
